(19) United States
(12) Patent Application Publication
(10) Pub. No.: US 2007/0242743 A1
(43) Pub. Date: Oct. 18, 2007

(54) Unipolar Electric Pulse Generator

(76) Inventor: Yves Scherman, Villejuif (FR)

Correspondence Address: Judy Jarecki-Black, 3239 Satellite Blvd, Duluth, GA, 30096, US

(21) Appl. No.: 11/559,468

(22) Filed: Nov. 14, 2006

(30) Foreign Application Priority Data
Nov. 14, 2005 (FR) 05 11532

(51) Int. Cl. H03K 7/08

(52) U.S. Cl. 375/238

(57) ABSTRACT

Device for improving in vivo penetration of molecules into cells, comprising a generator of square unipolar electric pulses, an electrode device electrically linked to the generator, and a means (8) of injecting the active agent into the tissues. The generator is adapted to generate a signal consisting of a series of square pulses at a low and constant voltage (611) in PWM (Pulse Width Modulation) mode in accordance to the form of the required pulses. The signal is used to divide a constant voltage current (631) output by a direct voltage source (530) and generate a current (641) having a required voltage (130).

### INCORPORATION BY REFERENCE

This application is a continuation-in-part of International Patent Application No. PCT/US2006/______ filed Nov. 13, 2006 (Application number to be assigned; attorney docket number MER 06-080PCT) which claims priority to French patent application Serial No. FR-05 11532 filed Nov. 14, 2005.

The foregoing application, and all documents cited therein or during their prosecution (“appln cited documents”) and all documents cited or referenced in the appln cited documents, and all documents cited or referenced herein (“herein cited documents”), and all documents cited or referenced in herein cited documents, together with any manufacturer's instructions, descriptions, product specifications, and product sheets for any products mentioned herein or in any document incorporated by reference herein, are hereby incorporated herein by reference, and may be employed in the practice of the invention.

### FIELD OF THE INVENTION

The present invention relates to a device for improving the administration of substances into in vivo tissues and into the cells of said tissues, by associating the injection of active agents with a physical process.

The physical process used is the administration of electric fields or electric currents. These fields and/or this current have the effect of temporarily permeabilizing the cells and also of improving the administration of the active agent into the tissue.

### BACKGROUND OF THE INVENTION

Electrotransfer or electropermeabilization involves the injection of an active agent, i.e., chemical molecule or nucleotide, into a tissue and the simultaneous or subsequent administration of electric current pulses, which permeabilize the walls of the tissue and/or cells and thereby promote the entry of the active agent.

This results in an electrophoresis or iontophoresis effect on the active agent, whereby the molecules of the active agent are driven by electric convection into the tissues, into the human, animal, plant or bacterial cells, and, in certain cases, into the nucleus of the cell.

In the present application, the term “electrotransfer” designates this method of using electric fields or electric currents to improve the administration of an active agent to biological tissues and enhance its effectiveness. The term “fields” is used as the electric or electromagnetic fields, and the electric current delivered between two electrodes subjected to different voltages.

Anti-tumour chemotherapy is one example wherein the penetration of chemical modules into tumour cells is necessary for a therapeutic activity according to the “electrochemotherapy” method.

DNA electrotransfer has the effect of promoting tissue and intracellular penetration of DNA. The electrotransfer of therapeutic expression cassettes, comprised of a promoter, gene, and polyadenylation sequence, can permit the expression of the gene. In the present application, the term “active agent” designates any molecule having a beneficial effect or used for analytical purposes such as imaging, functional, and in particular, all peptide or nucleic acid-type macromolecules. Among these nucleic acids, plasmids or linear DNA or RNA strands produced by synthesis are preferred. The invention also relates to any nucleic acid, protein, sugar or other genetically or chemically modified biological molecule, or even any entirely synthetic molecule, produced according to the methods of those skilled in the art.

Electrotransfer can be used in particular for augmenting the administration of DNA, plasmids or any other form of genetic material (DNA, RNA or other), leading to the expression of the gene product. This product can be RNA or a protein, particularly in tissues such as muscles, tumours, skin, nervous system or liver.

Electrotransfer requires a device comprising, at least, a generator of electric pulses and an electrode device.

U.S. Pat. No. 5,273,525 describes a syringe comprising two injection needles which also serve as electrodes.

PCT application WO-A-99/01158 describes the improvement of the transfer of nucleic acid into muscle provided by the use of unipolar square fields.

PCT application WO-A-99/01157 describes the enhanced transfer of nucleic acid into cells of pluricellular eucaryotic organisms.

PCT application WO-A-2006/010837 describes electrode devices and methods for improving the innocuousness and for lowering the toxicity of the electrotransfer described in this application.

US patent application US-A-2004/167458 describes an electrode system for facilitating the introduction of a macromolecule into cells of a tissue in a body or plant.

U.S. Pat. No. 6,241,701 describes an apparatus for in vivo electroporation therapy.

U.S. Pat. No. 6,010,613 describes a method for treating organic materials with pulsed electrical fields.

US patent application US-A-2005/0052630 describes an electroporation device used to facilitate the introduction of a macromolecule into cells of a tissue in a body or plant.

U.S. Pat. No. 5,869,326 describes an electroporation apparatus generating and applying an electric field according to a user-specified pulsing scheme.

PCT application WO-A-03/075978 describes the application of electrical energy to biological tissue in conjunction with injecting a composition that diffuses through the tissue.

Square pulse generators have already been produced. An exemplary method of producing a square pulse generator involves using a microcontroller to generate pulses at high frequency, then transferring the pulses to a transformer which amplifies the signal to the required voltage. Each burst of micro-pulses corresponds to a required final pulse, and the whole pulse is then transmitted to a filter, represented on FIG. 26a. A square pulse is thus obtained; however, the peak of the pulse may be in “sawtooth” form or with a decreasing slope due to the use of condensers, as shown on FIG. 26b, or the pulse may have a voltage with large variations as shown on FIG. 26c.

Another method of producing a square pulse generator is to use a cylinder, wherein only a strip along the axis of the cylinder is electrically conducting and is linked to a circuit generating direct current at the required voltage. This cylinder rotates within a second hollow cylinder on the same axis. This second hollow cylinder has an internal conductive strip, linked to a terminal which forms one of the terminals of the generator (the other terminal is linked to the earth). The two metallic strips periodically come into contact because of the rotation, thus causing the pulse to be generated. The duration of the pulse, and the period between two pulses, depends on the speed of rotation. The drawback of this generator is that it is a mechanical-based system, and digital systems are more accurate.

Electrotransfer technology was first used in chemotherapy in high voltage conditions, i.e. approximately 2000 V for pulses on the order of a few microseconds. It can also be applied to the electrotransfer of nucleic acids.

The existing generator technologies offer only approximately square pulses, in which the voltage is not constant on each pulse and dips at the end of each pulse. Furthermore, it is observed that the transition from zero voltage to the voltage of the pulse and vice-versa is quite long.

The electrotransfer of DNA can induce significant, even intolerable, pain, and muscular contractions that can cause serious, sometimes irreversible, sequelae. Muscular contraction can occur even if the subject is anaesthetized. Furthermore, in many cases, the weak or elderly state of the subject makes anaesthesia contra-indicative.

Citation or identification of any document in this application is not an admission that such document is available as prior art to the present invention.

### SUMMARY OF THE INVENTION

The present invention may encompass a powerful unipolar electric pulse generator. Associated with this generator, the present invention may propose invasive and non-invasive electrode devices and a method adapted to improving the effectiveness and the innocuousness of the electrotransfer method and to reduce its toxicity and the scale of the muscular contractions.

The present invention also may make it possible to optimally inject active agent solution into all tissues.

The present invention relates to a device and a method in which square or rectangular fields or electric pulses having determined characteristics are used to make an electrotransfer. As shown hereafter, this has the unexpected effect of improving the efficacy of electrotransfer, most likely by enhancing the amount of active agent introduced in the cells.

The invention also concerns identification of a square or rectangular form of electric fields that are particularly appropriate for the penetration of active agent in the tissue.

Thus, the invention provides for electrotransfer devices and methods that are better tolerated by the subject, in particular optimised field sequences.

In the present invention, the electrotransfer is performed in low field conditions. For example the voltage is unipolar, which is better tolerated, and less than 500 V.

Further, the invention provides for a generator adapted to generate pulses of specified form and voltage, which appears to enhance the efficacy of electrotransfer of nucleic acids, chemical molecules and other active agents into the cells.

The powerful devices and methods of the invention give field conditions that are better tolerated in regards to innocuousness. Further the device and methods are more effective and can compensate for the loss in the field amplitude in order to inhibit or diminish painful field conditions.

The term “delivering” or “delivery” of the fields is used in the present application to mean the generation by the device of a potential difference between the electrodes, thereby generating an electric current and/or electric fields between the electrodes.

In the present application, the term “set of electrodes” is used to mean a set of at least one electrode.

The improvement in the effectiveness is related to an improvement in the innocuousness, which occurs by reducing the parameters generating pain and muscular contraction.

Thus, the invention concerns a device for improving in vivo penetration of active agent molecules into cells of tissues of a human or animal subject, and may comprise the following:

(i) a generator of unipolar electric pulses that can produce at least one series of square unipolar electric pulses, wherein the generator comprises:
(a) a means to enter the required voltage for each series of pulses,
(b) a means to enter a number of pulses, a duration of each pulse and an interval between pulses, for each series of pulses,
(c) a means to generate a signal that consists of a series of square pulses at a low and constant voltage in PWM (Pulse Width Modulation) mode, and that is in accordance to the form of the required pulses (i.e., having the required interval, duration, number),
(d) a direct voltage source generating a current at a constant voltage greater than the highest required voltage for the pulses,
(e) at least one pulse generator circuit, using said signal to divide the current output by the direct voltage source and generate, at output terminals, a current having the required voltage and pulse form (i.e., interval, duration, number) characteristics required for the series of pulses,

(ii) at least one electrode device electrically linked to the at least one pulse generator circuit by output terminals, wherein each electrode device comprises:
(a) a first set of electrodes comprising at least one electrode electrically linked to a first terminal of the pulse generator circuit,
(b) a second set of electrodes comprising at least one electrode electrically linked to a second terminal of the pulse generator circuit,

(iii) a means of injecting the active agent into the tissues.

The means adapted to generate the signal consisting of a series of square pulses may comprise a computer signal source.

In the device, each pulse generator circuit may comprise:

(i) a power module comprising at least one transistor having a collector, a base and an emitter, and

(ii) a pulse amplifier circuit that comprises a means adapted to enter the required voltage for the pulses, and generates, from the signal consisting of the series of square pulses, a signal supplying the base of each transistor of the power module; the generated signal has a voltage equal to the required voltage, which is incremented by the voltage difference between the base and the emitter of each transistor of the power module. Also in the device, the direct voltage source may be linked to the collector of each transistor of the power module, and the power module may consequently deliver, via the emitter to the output terminals, a current. The form of the current corresponds to the series of pulses of the signal, and the voltage of the current corresponds to the required voltage for the pulses.

Each pulse generator circuit may have a current intensity control module adapted to limit, in real time to a predefined threshold, the current intensity of each pulse delivered at the output terminals. This occurs by inducing a variable resistance which accordingly modifies the voltage delivered at the output terminals.

Limiting the current intensity generated allows prevention of overload situations.

The current intensity control module may be adapted to cut off the current as the intensity between two electrodes reaches a predefined threshold.

The current intensity control module may comprise a measurement resistor and a control transistor having a collector, a base, and an emitter, controlled by the voltage difference across the measurement resistor. The transistor is linked to one end of the measurement resistor by the emitter, to the base of each transistor of the power module by the collector, and to the emitter of each transistor of the power module by the base that is also linked to the other end of the measurement resistor. Furthermore, the current intensity module can be used to reduce the current intensity emitted through one of two means:

(i) generating a current between the base and the emitter of each transistor of the power module as soon as the current intensity very slightly exceeds the threshold; the voltage reduction between the base and the emitter of each transistor of the power module has the effect of inducing a resistance in each transistor of the power module, and thus reduces the voltage between the output terminals; or

(ii) no longer generating any current between the base and the emitter of each transistor of the power module once the current intensity has fallen below the threshold.

Each power module may comprise at least one IGBT-type transistor or at least one MOSFET-type transistor

Each pulse amplifier circuit may comprise the following components:

(i) a direct voltage generator producing a voltage to the base of each transistor of the power module,

(ii) a generator circuit for the required signal, used to divide the voltage according to the signal that consists of the series of square pulses generated by the means; the circuit is comprised of the following components:
(a) an opto-isolator which serves as a switch and, according to the pulses of the signal that consists of the series of square pulses, is used to short circuit the base and the emitter of each transistor of the power module, thus rendering the emitted current zero at the output terminals of the generator during the period between two pulses,
(b) a transistor which also serves as a switch and, according to the pulses of signal that consists of the series of inverted square pulses obtained through an opto-isolator, is used to link the voltage of the base of each transistor of the power module to earth,
(c) a resistor between 20 kohms and 560 kohms located between the direct voltage generator and the switch transistor,
(d) a resistor between 10 kohms and 470 kohms located between the base of each transistor of the power module and the switch transistor.

Each pulse generator circuit may have a control means to collect information on the emitted signals and currents, and to transmit the information to a computer means that can automatically, in the case of an anomaly or a maximum current intensity threshold overshoot, may perform one of the following actions:

(i) stop the current before its arrival at the power module, using a circuit,

(ii) stop the generation of the signals,

(iii) signal the error situations to the operator,

(iv) take any pre-programmed logical action.

The emitted pulses at the output terminals of the generator may be characterized by the following:

(i) the voltage of the emitted pulses is equal and constant for each pulse and is less than 500 V,

(ii) the duration of the interval between the emitted pulses is equal between each pulse and is between 1 and 150 ms,

(iii) the duration of the pulses emitted is equal for each pulse and is between 1 and 100 ms,

(iv) the fields generated between each pair of electrodes are between 5 and 500 V/cm,

(v) the current intensity delivered at each instant while the fields are being delivered is less than 5 amps,

(vi) the total number of emitted pulses for each series is less than 25,

(vi) the number of series emitted simultaneously is less than 16, and

(viii) the total number of emitted series is less than 32.

The electrode device may comprise two invasive electrodes, where each electrode is linked to an output terminal of the generator, and a means of injecting the active agent. The means of injecting the active agent consists of an injection needle at an intermediate depth located at the centre of the two invasive electrodes, such that the electrodes and the injection needle are parallel, assembled, and joined together using a non-conducting support. The electrodes are of the same depth.

In a variant, the electrode device may comprise two sets of electrodes. The first set of electrodes may consist of a central invasive electrode and serve as a needle for injecting the active agent. The electrode is linked to a zero terminal of the pulse generator circuit. The second set of electrodes may consist of external invasive electrodes located approximately on a circle, wherein the central electrode is located at the centre and the external electrodes are equidistant from each other. Each external electrode is linked to another terminal of the pulse generator circuit, and the electrodes of the two sets are parallel, at the same depth, assembled and joined together using a non-conductive support.

The second set of electrodes may consist of four, three, or two invasive electrodes. In the case of the second set consisting of two invasive electrodes, the electrodes of both sets are aligned.

The invasive electrodes of each electrode device may be joined together using a non-conductive support. Each electrode device may also comprise a housing means having a compartment used to house the joined electrodes, the means of injecting the active agent, and a tank containing the active agent. This housing makes it possible to correctly handle the electrodes and to provide the electric link between each set of electrodes and its output terminal.

The housing may have a means for successively driving the invasive electrodes into the tissues to predefined intermediate depths, and a means for injecting the active agent at stop position.

The upper part of the invasive electrodes of each electrode device, which penetrates into the tissues, may be covered by an electric insulator.

The device may comprise only one pulse generator circuit, simultaneously emitting a single series of pulses to two terminals linked to a single electrode device.

The invention further concerns a method using a device as described above to improve in vivo penetration of active agent molecules into cells of tissues of a human or animal subject. This method comprises the following steps:

(1) placing at least one group of electrodes in contact with the tissues, each electrode of the first set of electrodes being electrically linked to a terminal of a pulse generator and each electrode of the second set of electrodes being electrically linked to another terminal of a pulse generator,

(2) injecting the active agent into the tissues,

(3) setting the number of pulses, the duration of each pulse and the duration between pulses for each series of pulses to be delivered,

(4) setting the required voltage for each series of pulses to be delivered,

(5) delivering square unipolar electric pulses, in which the electric pulses is produced by the generator in the following manner for each series of pulses:
(a) a signal is generated, at a constant low voltage in PWM (Pulse Width Modulation) mode, the signal corresponding to the form of the pulses required, i.e., interval, duration, and number,
(b) said signal is used to divide the current output by a direct current source and to generate the required pulses in the correct form, interval, duration, and number; the generated current is raised to the required voltage.

The method may further comprise a step wherein, for each series of pulses to be delivered, the required voltage, number, duration, and interval of the pulses are set according to the distance between the electrodes and the geometry of the electrodes.

Before delivering the square unipolar electric pulses, the following steps may be carried out:

(1) driving the electrode device successively into the tissues at intermediate depths, wherein the electrode device comprises at least two invasive electrodes, each linked to a terminal of a pulse generator circuit, and contains a means of injecting active agent,

(2) injecting the active agent into the tissues at successive depths using the electrode device, in which the active agent is injected at the centre of the device,

(3) driving all of the invasive electrodes to a predefined final depth, in which the invasive electrodes are introduced to the same depth into the tissues and along the same axis.

Furthermore, the invention concerns a device for improving in vivo penetration of active agent molecules into cells of tissues of a human or animal subject, wherein said device comprises:

(i) a generator of unipolar electric pulses adapted to generate at least one series of square unipolar electric pulses. The pulses are geometrically defined such that the voltage variations about a required voltage for each pulse are less than 5% of the required voltage, and the duration for the voltage to reach the required voltage from zero voltage (the ascendant phase of each pulse) and the duration for the voltage to reach zero voltage from the required voltage (the descendant phase of each pulse) are less than 5% of the duration of the pulse,

(ii) at least one electrode device electrically linked to output terminals of the generator, each electrode device comprising two sets of electrodes; The first set of electrodes comprises at least one electrode electrically linked to a first terminal of the generator, and the second set of electrodes comprises at least one electrode electrically linked to a second terminal of the generator,

(iii) a means of injecting the active agent into the tissues.

In a particular embodiment of the invention, the pulses may be geometrically defined such that the voltage variations about the required voltage for each pulse are less than 1% of the required voltage, the duration of ascendant phase the descendant phase of each pulse are less than 1% of the duration of the pulse.

The invention also provides for a method implementing such a device, to improve in vivo penetration of active agent molecules into cells of tissues of a human or animal subject, the method comprising the following steps:

(1) placing at least one electrode electrically linked to the first terminal of the pulse generator and at least one electrode electrically linked to the second terminal of the pulse generator in contact with the tissues, and injecting the active agent into the tissues,

(2) delivering square unipolar electric pulses by the generator, wherein the amplitude of said pulses are calculated according to the distance between the electrodes; this is to create an electric field between the electrodes such that at least a part of the electric pulses are geometrically defined such that the voltage variations about the required voltage for each pulse are less than 5% of the required voltage, or the duration of ascendant phase and descendant phase of each pulse are less than 5% of the duration of the pulse.

Accordingly, it is an object of the invention to not encompass within the invention any previously known product, process of making the product, or method of using the product such that Applicants reserve the right and hereby disclose a disclaimer of any previously known product, process, or method. It is further noted that the invention does not intend to encompass within the scope of the invention any product, process, or making of the product or method of using the product, which does not meet the written description and enablement requirements of the USPTO (35 U.S.C. 112, first paragraph) or the EPO (Article 83 of the EPC), such that Applicants reserve the right and hereby disclose a disclaimer of any previously described product, process of making the product, or method of using the product.

It is noted that in this disclosure and particularly in the claims and/or paragraphs, terms such as “comprises”, “comprised”, “comprising” and the like can have the meaning attributed to it in U.S. patent law; e.g., they can mean “includes”, “included”, “including”, and the like; and that terms such as “consisting essentially of” and “consists essentially of” have the meaning ascribed to them in U.S. patent law, e.g., they allow for elements not explicitly recited, but exclude elements that are found in the prior art or that affect a basic or novel characteristic of the invention.

These and other embodiments are disclosed or are obvious from and encompassed by, the following Detailed Description.

### BRIEF DESCRIPTION OF THE DRAWINGS

The following detailed description, given by way of example, but not intended to limit the invention solely to the specific embodiments described, may best be understood in conjunction with the accompanying drawing, in which:

FIG. 1 summarizes the main modules of the pulse generator delivering square unipolar pulses at the required voltage.

FIG. 2.a describes an exemplary series of unipolar pulses.

FIG. 2.b describes an exemplary series of unipolar pulses, in which the current intensity reaches the threshold and is controlled by the current intensity control module.

FIG. 3.a diagrammatically represents the electrotransfer method using a device with two electrodes in profile view.

FIG. 3.b diagrammatically represents the electrotransfer method using a device with two electrodes in top view.

FIG. 3.c diagrammatically represents the electrotransfer method in a top view, wherein the active agent is located between the electrodes.

FIG. 4 illustrates a profile view of an exemplary device with an electrode of a first set positioned in the centre of the active agent and with a sign opposite to other two electrodes flanking the active agent.

FIG. 5 illustrates a top view of an exemplary device with an electrode of the first set positioned in the centre of the active agent and with a sign opposite to other eight external electrodes flanking the active agent.

FIG. 6.a illustrates the fields delivered by a device with an electrode placed between two external electrodes with opposite signs, wherein the external electrodes are located equidistant from each other.

FIG. 6.b illustrates the fields delivered by a device with an electrode placed between four external electrodes, with opposite signs, wherein the external electrodes are located equidistant from each other.

FIG. 6.c illustrates the fields delivered by a device with an electrode placed between three external electrodes with opposite signs, wherein the external electrodes are located equidistant from each other.

FIG. 7 diagrammatically represents an exemplary device where the two electrodes are positioned flanking the active agent, wherein the injection means 8 is located in the centre of the device and is of lesser depth than the two electrodes 10, 11.

FIG. 8.a illustrates an exemplary device comprising three electrodes and one injection needle positioned in the centre of the device at intermediate depths.

FIG. 8.b illustrates an exemplary device comprising three electrodes and two injection needles positioned in the centre of the device at intermediate depths.

FIG. 9.a illustrates an exemplary device featuring an injection needle electrode at the centre, wherein the active agent is delivered once the electrodes are driven into the tissues FIG. 9.b illustrates an exemplary device featuring an injection needle electrode at the centre, wherein the active agent is delivered once the electrodes are delivered at an intermediate depth.

FIG. 9. c illustrates an exemplary device featuring an injection needle electrode at the centre, wherein the active agent is delivered once the electrodes are driven in as far as the guard.

FIG. 10.1 illustrates an exemplary device in which three invasive electrodes are partly electrically insulated using an insulating film.

FIG. 10.2 illustrates an exemplary device in which the central electrode is partly electrically insulated using an insulating film FIG. 10.3 illustrates an exemplary device in which the external electrode is non-invasive, wherein the invasive electrode is partly electrically insulated using a plastic film.

FIG. 11 illustrates an exemplary device designed to be used without housing, wherein the electrodes are joined together.

FIG. 12.a illustrates an example of a part that forms a device according to the invention, namely the housing.

FIG. 12.b illustrates an example of a part that forms a device according to the invention, namely an electrode device.

FIG. 12. c illustrates an example of a part that forms a device according to the invention, namely an end-stop system.

FIG. 13 illustrates an exemplary injection part placed in its housing compartment.

FIG. 14 illustrates an exemplary locking ring sliding along the closed housing.

FIG. 15 illustrates an exemplary locked device ready to be applied to the subject.

FIG. 16.a illustrates an example of a catheter electrode.

FIG. 16.b illustrates an example of a catheter electrode.

FIG. 16. c illustrates an example of a catheter electrode.

FIG. 17 illustrates an exemplary device consisting of a non-invasive electrode and an invasive electrode; in order to reach the tissue area, the invasive electrode is passing through the tissues along an axis approximately parallel to the plane of the non-invasive electrode placed on the tissues.

FIG. 18 illustrates an exemplary device consisting of a non-invasive electrode and an invasive electrode; to reach the tissue area, the invasive electrode is passing through the tissues along an axis approximately perpendicular to the plane of the non-invasive electrode placed on the tissues.

FIG. 19 illustrates an exemplary device consisting of a non-invasive electrode and an invasive electrode, in which the invasive electrode is passing through the non-invasive electrode through an orifice, and the position and the angle of the axis of the needle is guided by a guide device.

FIG. 20.a illustrates exemplary non-invasive electrodes having a disc shape with an orifice in its centre.

FIG. 20.b illustrates exemplary non-invasive electrodes having a horseshoe shape.

FIG. 20.c illustrates an exemplary non-invasive electrode consisting of several flat non-integral electrodes.

FIG. 21.a illustrates the field lines propagating under the surface of the tissues, between the non-invasive electrodes with electrodes in wire or spike form, on a surface that is flat.

FIG. 21.b illustrates the field lines propagating under the surface of the tissues, between the non-invasive electrodes with electrodes in wire or spike form, on a surface that is rounded.

FIG. 21.c illustrates an exemplary device consisting of two wire electrodes in parallel held in place by an adhesive tape.

FIG. 22 illustrates the fields delivered for a device consisting of two pairs of electrodes, in which the pulses (or series of pulses) are alternately delivered to each pair.

FIG. 23 describes an exemplary generator in a preferred embodiment of the invention delivering square unipolar pulses at the required voltage.

FIG. 24 describes the method of generating waves of exactly square form at the required voltage in a preferred embodiment of the invention, and the current intensity limiting circuit.

FIG. 25a illustrates the generator/electrode connections for a device with three aligned electrodes and three terminals on the generator, each electrode being connected to its own terminal.

FIG. 25.b summarizes the main modules of the generator emitting two simultaneous series of pulses using two circuits, to a device with three aligned electrodes, in which the central electrode is linked to the earth, common to each circuit.

FIG. 26.a is schematic illustration of a pulse consisting of high frequency sinusoidal pulses.

FIG. 26.b is schematic illustration of a pulse having a peak and a progressive slope at the end of the pulse.

FIG. 26.c is schematic illustration of a pulse having significant voltage variation.

FIG. 26.d is schematic illustration of an example of a pulse according to the invention, in which the geometrical features of the field are defined by the parameters t1, t2, T and V1-V2.

FIG. 27.a represents a result of the use of the generator of the present invention by DNA electrotransfer in a skeletal muscle.

FIG. 27.b represents a result of the use of the generator of the present invention by DNA electrotransfer in a skeletal muscle.

FIG. 27.c represents a result of the use of the generator of the present invention by DNA electrotransfer in a skeletal muscle.

FIG. 28 represents the form of a pulse generated by the generator of the present invention.

### DETAILED DESCRIPTION OF THE INVENTION

The present invention can be used to inject an active agent solution into all tissues, in particular into muscle, tumours, joints, the dermis and epidermis, and into all organs except for the heart, and in particular the bladder, stomach, kidneys, lungs, and all the organs of the head, including in particular the brain, the ears, the eyes, the throat, of an animal or human, living or not, and to deliver the fields in order to permeabilize the tissues and promote the transfer of the active agent into the cells.

The device according to the invention comprises a square unipolar electric pulse generator, an electrode device 23 linked to the generator 21, and a means of introducing the active agent into the tissues.

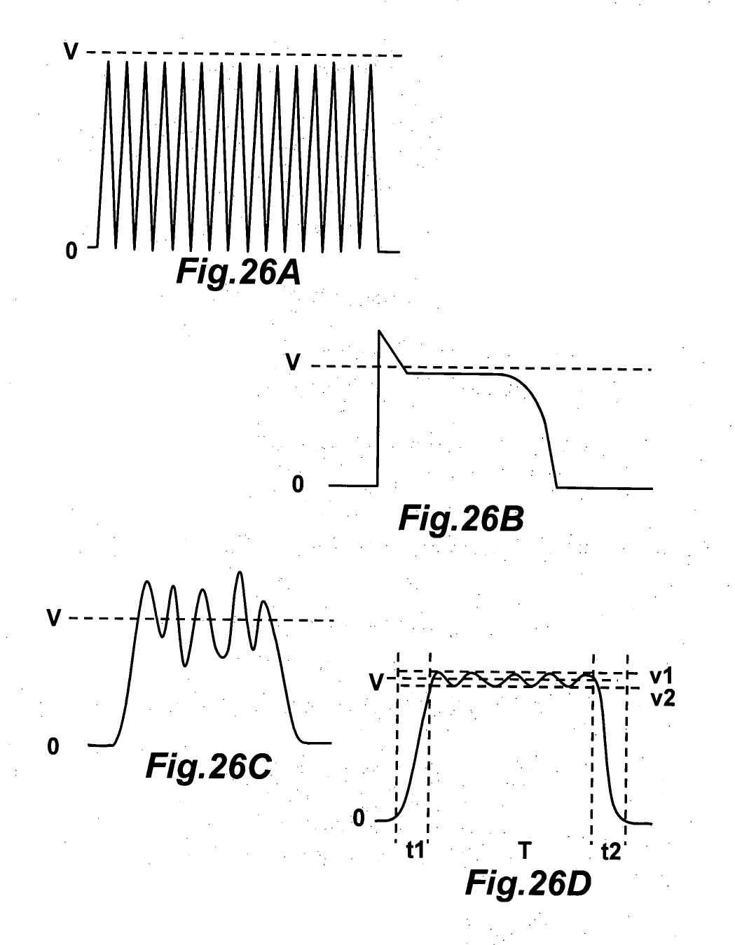

The generator 21 may be adapted to generate improved square fields or square pulses which can be understood as a field or a pulse of an improved type having a global square or rectangular form as illustrated on FIG. 26d. Voltage variations between v1 and v2 about a required voltage V for the field or the pulse are reduced and do not exceed, on average and/or in absolute magnitude, a low percentage of the impulsion. The variations of a pulse are taken into account within the duration T, i.e. between the moment at which the voltage finishes the ascendant phase, at the beginning of the pulse, and the moment at which the voltage starts the descendant phase, at the end of the pulse. The duration t1 of the ascendant phase of the voltage, i.e. substantially from zero voltage to the required voltage V, and duration t2 of descendant phase of the voltage, i.e. substantially from the required voltage V to zero voltage, are reduced and do not exceed a determined percentage of the duration T of the pulse. Here, t1 is the duration between the moment at which the voltage begins the ascendant phase from zero voltage and the moment at which the voltage reaches the required voltage and finishes the ascendant phase. T2 is the duration between the moment at which the voltage begins the descendant phase from nearly the required voltage V and the moment at which the voltage reaches zero voltage and finishes the descendant phase.

Square fields or square pulses of the above mentioned type also integrate fields or series of pulses in which only a part of the fields or the pulses are square.

In a particular embodiment, the above mentioned percentage can have values less than 5%. Hence, the pulse can be geometrically defined such that the voltage variations, v1 and v2, about the required voltage V for the pulse are less than 5% of the required voltage V, and the durations t1 and t2 are less than 5% of the duration T of the pulse.

Furthermore, the above mentioned percentage can have values less than 1% such that the pulse can be geometrically defined with voltage variations v1 and v2 are less than 1% of the required voltage, and durations t1 and t2 are less than 1% of the duration of the pulse.

Square field or square pulse of this type may be obtained by hatching a constant current generated by a DC voltage source. For example, the generator may generate a field and a constant current in a basal way, wherein said field is interrupted suddenly at controlled regular intervals, thus generating at least a series of square unipolar electric pulses. This series comprises at least one square unipolar electric pulse.

In particular, the generator 21 may be adapted to generate a constant low voltage signal in PWM (Pulse Width Modulation) mode and with the required pulse form. This signal can then be used to divide a constant voltage current of a direct voltage source to the required voltage 130 and the required form.

Such a generator 21 may be advantageously used to generate the square pulse or series of square pulses of the above mentioned improved type.

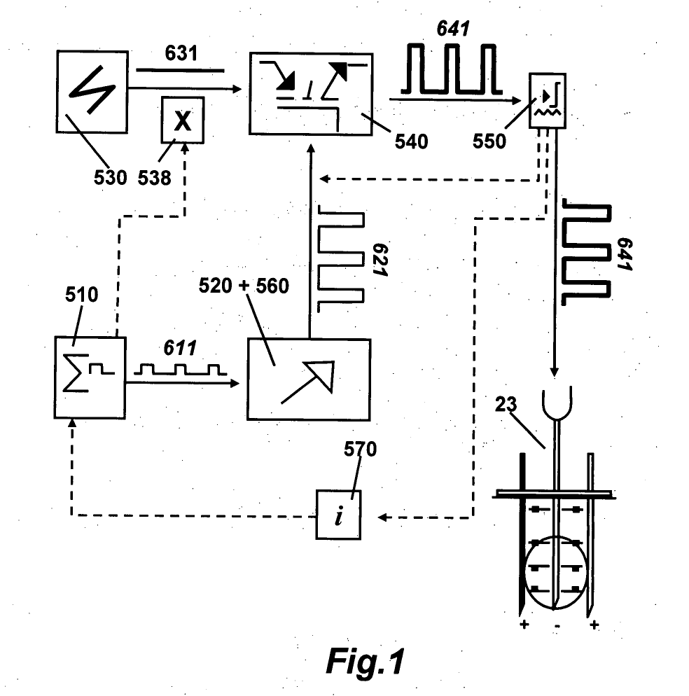

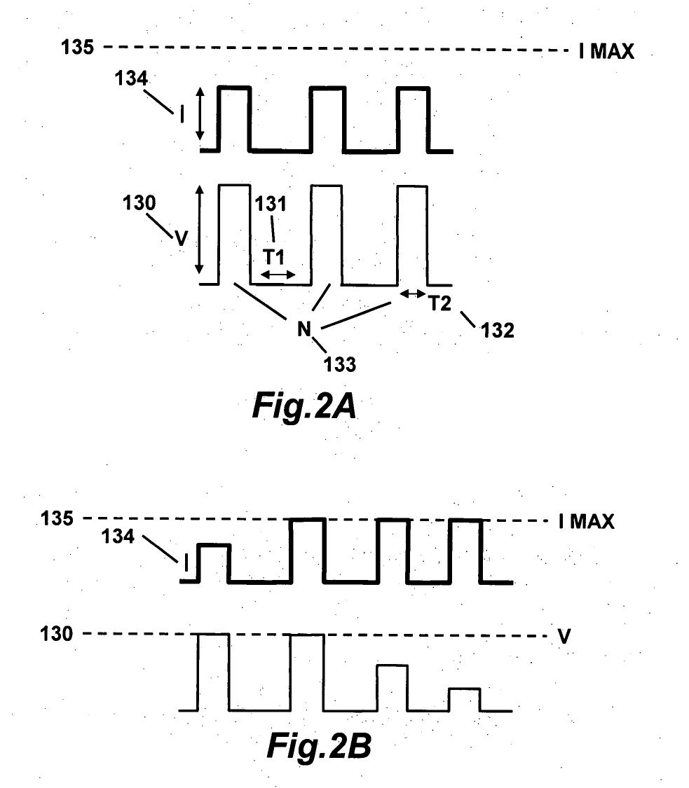

As illustrated in FIGS. 1 and 2.a, a direct current source 530 at sufficiently high voltage may emit a direct current 631 to a module, hereinafter called power module 540. This module comprises one or several transistors each having a collector 542, a base 543, and an emitter 544. The current 631 may be emitted to the collector 542 of each transistor 541, which can be arranged in parallel. At the same time, a low voltage electric signal 611 consisting of a series of at least one square pulse may be generated in PWM mode. It can be generated by a computer means 510.

The term “computer means” includes processors, microprocessors, controllers, microcontrollers, a combination of the same, and all associated memories and electronic components. Any devices that are useful or necessary to their operation are also included. The signal consisting of a series of square pulses 611 can also be generated by an electronic circuit, but this device has many disadvantages compared to a computer means solution.

The pulses may be transmitted to a required signal generator circuit 520 which, combined with a direct voltage generator 560, carries the pulses at a voltage U130a greater than the required final voltage 130 to the base 543 of each transistor 541 of the power module 540. As a result, the desired pulses 641 can be generated by the emitter of each transistor 541 at the required voltage 130. The voltage U130a is calculated according to the transistors used in order to obtain the required voltage 130 at their emitter 544.

A current regulator 550 may then be used to prevent the current from exceeding a predefined current intensity threshold 135. The pulses 641 can then be transmitted to the electrode device 23 implanted in the tissues where the active agent has previously been injected in order to deliver the fields between the electrodes.

The main function of such a generator is to emit a series of square unipolar pulses with a predefined number of pulses 133 but at least one pulse, a predefined pulse duration 132 and a predefined interval 131 between pulses. In an embodiment of the invention, the voltage of each pulse may be identical. The voltage can be defined by a potentiometer or any other means known to those skilled in the art.

As illustrated in FIG. 1, the generator may comprise a direct voltage source 530 adapted to obtain the required current intensity. The voltage can take any value greater than the maximum voltage U130a which is a function of the required voltage for the pulses 130 to be delivered to the electrode device 23. For example, the voltage of the direct voltage source 530 can take a value of 265 V to obtain maximum voltage for the pulses U130a of 269 V, making it possible to obtain a required voltage 130 of 250 V. All techniques known to those skilled in the art of producing a direct current can be used.

In a more detailed manner, the generator may comprise a signal source which emits an electric signal consisting of a series of square pulses 611 generated in PWM mode with a constant low voltage. This electric signal consists of a number of pulses 133 with a pulse duration 132 and an interval 131 between two successive pulses. The characteristics of the signal 611 are predefined before triggering the generation of the pulses. All techniques known to those skilled in the art of producing this signal can be used. The signal 611 can be generated by a computer means, and the voltage delivered is defined by the properties of such computer means. Thus, according to the current technology, the voltage may vary between 2.7 V and 5 V. Generation of a 5 V signal (TTL pulses) may be more appropriate for interfacing the computer means with other devices.

The signal 611 may be amplified to the required voltage U130a using a pulse amplifier circuit 520, 560 which may comprise a direct voltage generator circuit 560 adapted to generate a voltage at the amplitude U130a according to the voltage 130 defined by the operator, using, for example, a potentiometer, and a required signal generator circuit 520 adapted to divide the voltage emitted by the circuit 560 into pulses, corresponding to the pulse signal 611.

The resulting signal 621 output by the pulse amplifier circuit 520, 560 may be emitted to the base 543 of each transistor 541 of the power module 540.

The power module 540 may comprise at least one transistor 541 and is used as a switch controlled by the signal 621. It can be used to divide up the current 631 generated by the direct voltage source 530 (at the voltage U130a) into required pulses (at the voltage 130). The desired final series of pulses 641 can thus be obtained, namely with the form of the amplified signal 621 at the required voltage 130 and at a current intensity supported by the direct current source 530.

In an embodiment of the invention, the transistors 541 used by the power module 540 are of the IGBT type. There are many advantages associated with the IGBT transistor as compared to a conventional transistor. For example, the base 543 can be controlled with very little current and causes less voltage loss at the output, thereby becoming more accurate. Also, the open base is perfectly insulated. Finally, the IGBT transistor is characterized by a low resistance in conduction mode and can therefore withstand a high current intensity for a certain duration without fusing.

These characteristics of the transistor are important because the appliance needs to generate low frequency pulses at less than 100 hertz with an amplitude that can be as high as several hundred volts, in addition to supporting a current intensity up to 5 A per pulse.

In another embodiment of the invention, the transistors 541 of the power module 540 can be of MOSFET type, but they are less appropriate.

A control of the excessively high current intensity phenomena, even short circuit, may be provided while the pulses are being delivered.

In practice, when invasive electrodes close to one another are used, the muscular contraction of the subject, caused by the emission of the first pulses can deform the needles and significantly reduce their distance. This can also cause an excessively high current intensity that is extremely painful for the subject, even toxic. The deformation of the needles can also cause a short circuit and destroy certain components of the generator, such as transistors, since the reaction time of a conventional fuse is too long for the electronic circuit of the generator which can be damaged.

For pain and toxicity reasons, the reaction time concerning high current intensity phenomena and short circuit should be brought down to the millisecond. However, conventional current cut off systems have a reaction time that is greater than a few milliseconds. It can then be useful to have a module for controlling current intensity functioning in a substantially instantaneous way and for limiting the current intensity until the current cut-off occurs.

Thus the generator may comprise a module 550 for controlling the current intensity emitted 134, making it possible in real time to limit the latter to a predefined threshold 135, as illustrated in FIG. 2.b. This module is adapted to reduce the output voltage 130 in proportion to the reduction in the resistance of the tissues, once the threshold 135 is reached. This has a further advantage of keeping the field value of the electric pulses between the electrodes approximately constant, thereby maintaining required therapeutic conditions.

The generator may also comprise a means 570 for controlling the emitted current by transmitting in real time the value of the emitted current intensity to a comparative analysis means. The comparative analysis means comprises a circuit 572 for rapidly comparing the information received with certain predefined values. In the event of an anomaly, such as zero current intensity or current intensity greater than a certain threshold, or if a transistor 541 is damaged, the analysis means transmits the information to the low signal 611 generator such as the microcontroller, or to any other computer control means. Any other means for collecting information on anomalies can be implemented to send the information to the computer control means. Such a control means comprising the analysis means may have a reaction time that is less than 100 milliseconds, and even less than 50 milliseconds.

The coupling of the above mentioned control module 550 and control means 570 permits limiting, in real time and substantially instantaneously, the current intensity with a current cut-off that can occur in less than 100 milliseconds. This may guarantee the subject against the pain and toxicity risks due to a short circuit phenomenon or a rapid increase of the intensity.

In a preferred embodiment, the signal generation means and the computer means of the generator will be combined in a single component, the microcontroller 510; however, the signal generator means and the computer means of the generator can consist of independent and interconnected components.

The microcontroller 510, which can have a short response time, such as on the order of a tenth of a millisecond, will take the appropriate decisions. It can, in particular, stop the passing of current if programmed in this manner. To do this, it can stop the generation of the low signal 611, and/or open a relay 538 controlling the passage of the current 631 from the direct current source 530 to the power module 540 in order to cut the current source 530 (in particular, if the power transistor 541 of the power module 540 is damaged and generates a short circuit between emitter and collector).

The required final pulses 641 can be transmitted to the electrodes by electric wire. For each pair of electrodes, wherein said pair comprises an electrode of a first set and an electrode of a second set, the generator may produce one or more predefined sequences of electric pulses according to the following characteristics in practice for each sequence:

(i) the voltage 130 of the emitted pulses is equal and constant for each pulse and is less than 500 V,

(ii) the duration of the interval between the emitted pulses 131 is equal between each pulse and is between 1 and 150 ms,

(iii) the duration of the emitted pulses 132 is equal for each pulse and is between 1 and 100 ms and

(iv) the fields generated between each pair of electrodes 100, 101 are between 5 and 500 V/cm,

(v) the current intensity 134 delivered at each instant that the fields are being delivered is less than 5 amps,

(vi) the total number of emitted pulses 132 in each series is less than 25, and

(vii) the total number of emitted series is less than 32.

Further, the duration between two pulse sequences may be less than 600 sec, and the number of sequences may be less than 25. The current intensity delivered may be less than 5 amps.

The electrode device 23 of the invention may consist of two sets of electrodes and a means of injecting the active agent 36. The first set of electrodes 11 consists of at least one electrode, wherein the electrodes are linked to a terminal of an electric pulse generator 21. The second set of electrodes 10 consists of at least one electrode, wherein the electrodes are linked to another terminal of the electric pulse generator 21. Therefore the second set of electrodes have a voltage that is different from the first set of electrodes.

The pulses can be emitted to each pair simultaneously or in succession.

The means of injecting the active agent can consist of one or more needles. The means of introducing the active agent can also occur under pressure using, for example, a pressure gun, by patch or by any other means known to those skilled in the art.

In the present application, the expression “electrode” denotes any type of electrode, in particular solid or hollow, invasive or non-invasive. The term “invasive electrode” denotes an electrode designed to penetrate inside the tissues, in particular any electrode taking the form of a solid or hollow needle (particularly a medical injection needle). The term “non-invasive electrode” denotes an electrode designed to remain on the surface of the tissues.

Each of the two sets of electrodes 11, 10 consists of one or more invasive electrodes and/or one or more non-invasive electrodes.

The invasive and non-invasive electrodes can be made of metallic materials, preferably non-oxidizable and of medical quality.

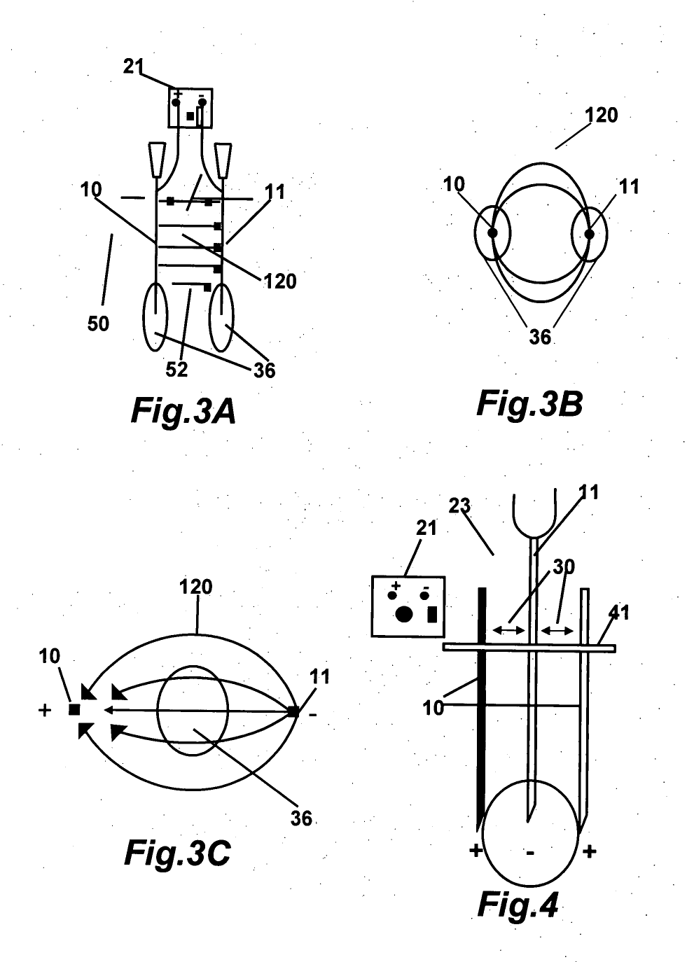

An exemplary device with two invasive electrodes 10, 11 is described in FIGS. 3.a and 3.b. FIG. 3.c represents the fields 120 passing through an active agent area 36 located between two electrodes 10, 11.

If the electrodes of the second set are non-invasive, then the second set of electrodes can be positioned on the surface of the tissues on the site where the active agent is injected. If the device has more than one invasive electrode, then the invasive electrodes all can have the same depth.

An invasive electrode device where the first set of electrodes 11 can be introduced within the active agent, preferably at its centre, and be surrounded by the second set of electrodes 10, is illustrated in FIG. 4 with a device with two external electrodes seen in profile.

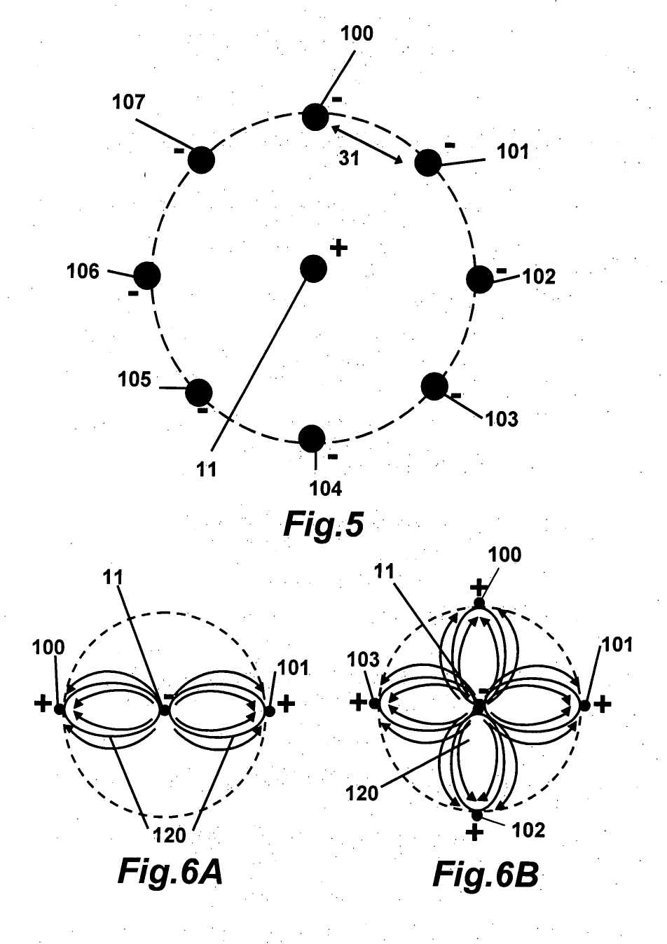

FIG. 5 illustrates a device with eight external electrodes seen from above.

Hereinafter in the description, unless otherwise specified, the electrodes of the first set of electrodes 11 consist of a single invasive electrode, called central electrode. The second set of invasive electrodes 10, 100, 101 will often be called “external electrodes”.

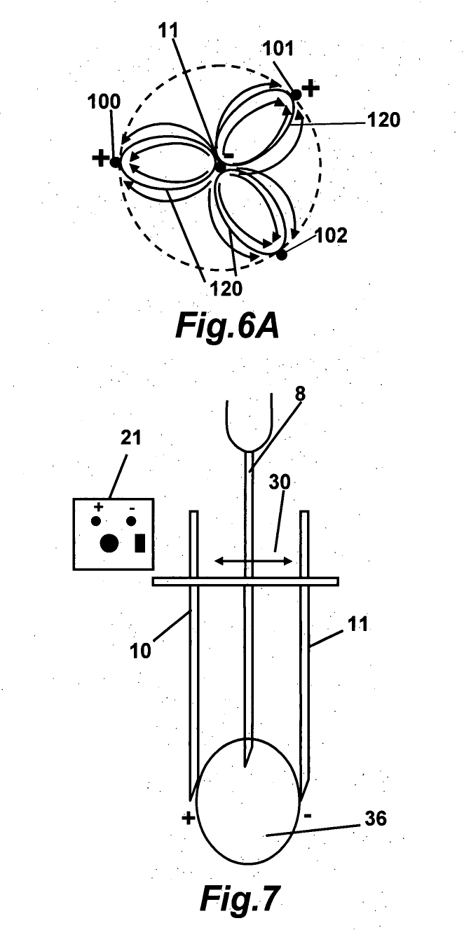

To improve the effectiveness of the transfer of active agent into the cells, the electrodes of the second set 100 to 107 can be distributed evenly, forming a circle with the central electrode 11 being the centre. FIGS. 6.a and 6.b illustrate the surface area electrotransferred with a device in which the second set of electrodes consists respectively of two electrodes 100, 101 and of four electrodes 100 to 103.

The distance 30 between the electrodes can be halved compared to a device with two electrodes (FIG. 7) and therefore may offer a more tolerable configuration by reducing the voltage and the distance between the electrodes to obtain a field of the same value. According to the device illustrated in FIG. 7, the injection means 8 can be located at the centre of the device and be of lesser depth than the two electrodes so that the active agent can be correctly located between the two electrodes.

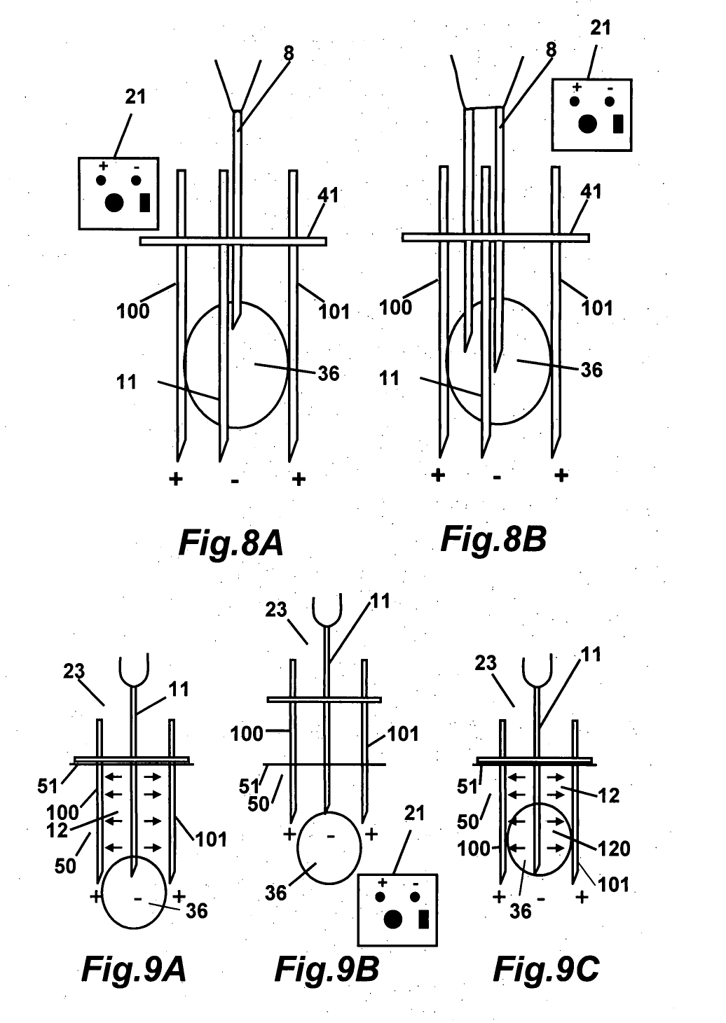

In order to accurately position the first set of electrodes at the centre of the active agent, the injection needle 8 of the active agent and the electrodes 11, 100, 101 can be secured relative to each other using one or more non-conducting clamping parts 41, which can be used to maintain it in a defined geometry. This is exemplified in FIG. 8.a.

In order for the active agent to be correctly located between the electrodes as exemplified in FIGS. 7, 8.a and 8.b on a device with three invasive electrodes, the injection needle(s) 8 should have a depth less than that of the central electrodes 11 and/or of the external electrodes 100, 101.

The central electrode can also serve as an injection needle (FIG. 9.a). However, the drawback of this device is that some of the active agent is diffused under the central needle electrode, and is no longer passed through by the fields (FIG. 9.a).

A method proposed by the invention, exemplified in FIGS. 9.b and 9.c, would be to inject the active agent 36 at one or more intermediate depths in the tissues 50. The electrode device 23 may be driven at each step more deeply into the tissues, in order to inject the active agent. In the last step, the electrodes may be driven in as far as the guard, without delivering any active agent.

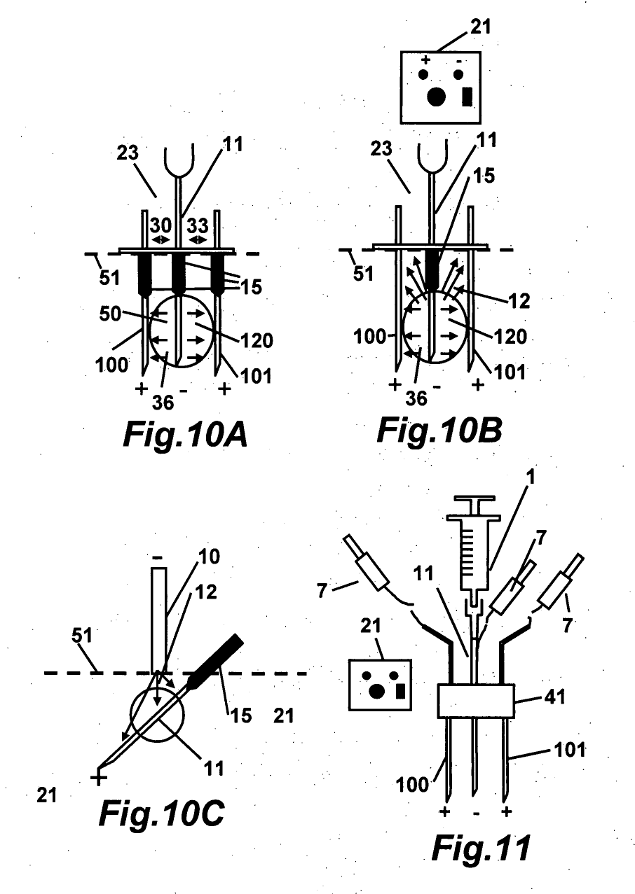

However, the fields 12 are also diffused into tissues containing no active agent. This can cause toxicity and a contraction or pain in the subject that is needless and superfluous. An electric insulator 15 can be applied to the upper part of the needles 100, 101, 11, as exemplified in FIG. 10.1 for a device with three invasive electrodes, so as to limit the quantity of current passing through the tissues. If only the needles attached to a single terminal of the generator are insulated, the stray currents 12 will be only partly reduced as illustrated in FIG. 10.2. It may thus be of interest to insulate the upper part of the invasive electrode for a device comprising one or more non-invasive electrodes (exemplified in FIG. 10.3).

The needles and the invasive or non-invasive electrodes can be joined together and clamped by a rigid or slightly flexible non-conducting support 41. The invasive components can then be parallel. An example is shown in FIG. 11 for a device with invasive needles 100, 101, the invasive electrodes passing through an electrically insulating block 41, while being directly linked to the generator 21 by an electric wire 7.

In the interests of a disposable and economical electrode device, the device can also comprise a housing 6 enabling the electrodes to be linked to the generator. This housing will enable the electrode device to be handled, so it can then easily be manipulated and the manipulator will be insulated from electric currents. The housing can also incorporate the injection means and a tank 1 for the active agent.

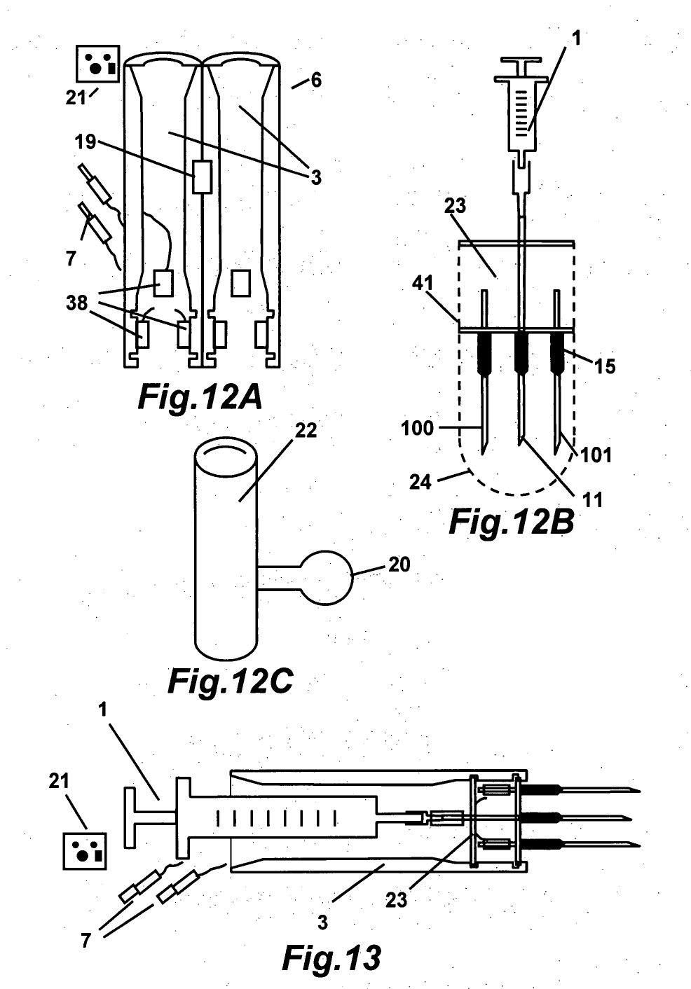

Furthermore, the housing 6 can make it possible to drive the electrode device to predefined depths, for example using stops 22. An example of disposable electrode device 23, of housing 6 with its stop system 20, 22 is shown in FIGS. 12.a, 12.b and 12.c. The method of assembling this exemplary housing 6 and the electrode part 23 and its stop is shown in FIGS. 13 to 15 and described later in the present application.

The stop system can also consist of an obstacle with predefined thickness, for example 5 mm, comprising a sleeve and being positioned between the tissues and the electrode device in order to maintain the electrode device at a predefined distance from the tissues when injecting the active agent. It can be withdrawn once the active agent is injected in order to drive in the electrode device as far as the guard. The obstacle can be horseshoe-shaped.

In order to facilitate the electrotransfer treatment, the housing 6 can contain a device which, by finger pressure, emits a signal (electric, electromagnetic or a wave) triggering the generation of the pulses.

The invasive electrodes can be adapted for the treatment of sensitive areas in order not to injure the treated area with the needle due to the muscular contraction caused by the delivery of the fields.

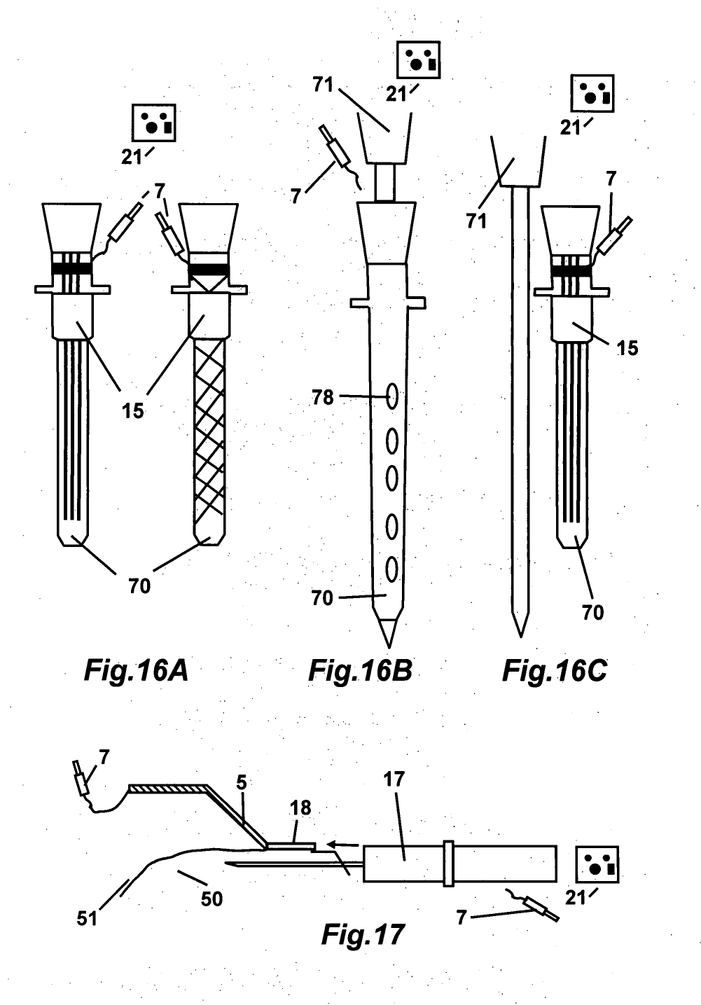

A “catheter” electrode, illustrated in FIGS. 16.a and 16.b, can be an invasive electrode, consisting of an invasive needle 71 covered with a catheter 70. A catheter is a tube made of materials that are thin, flexible and resistant to compression forces along their axes, for example silicone. It can be designed to be introduced into the tissues using the needle 71 placed inside the catheter and pointed at its end. The surface of the catheter is made electrically conductive, while allowing it to retain a certain flexibility. For example, the surface may be a metallic film or braid 72, except on the upper part 15 which may be non-conductive. Once the catheter electrode is inserted into the tissues, the needle is partially retracted, or even fully retracted from the device. The catheter 70, serving as an electrode, cannot then damage the tissues. The catheter electrodes can also be formed by a catheter that is insulating but with orifices 78, as exemplified in FIG. 16.c. Here, the conductive needle is withdrawn only partially at the moment when the fields are delivered.

In an embodiment of the invention, all or some of the electrodes of the second set of electrodes may be non-invasive, joined or not to the first set, and positioned on the surface of the tissues covering (or close to) the area containing the active agent.

The surface of each non-invasive electrode in contact with the tissues at the moment of delivery of the fields can be of any size. It can be very small, such as a point slightly flattened at its end. It can be larger, so that it can, for example, more significantly cover the area of the tissues containing the active agent, or cover a much greater area. It can be of any shape-rectangle, triangle, semicircle, arc of circle, disc, oval, etc. Each electrode can have a sleeve and an orifice 43, as exemplified in FIG. 20.a (circle) and 20.b (horseshoe), which enables the invasive electrodes to pass through it. FIG. 20.c illustrates an example of non-invasive electrodes consisting of several non-integral flat electrodes.

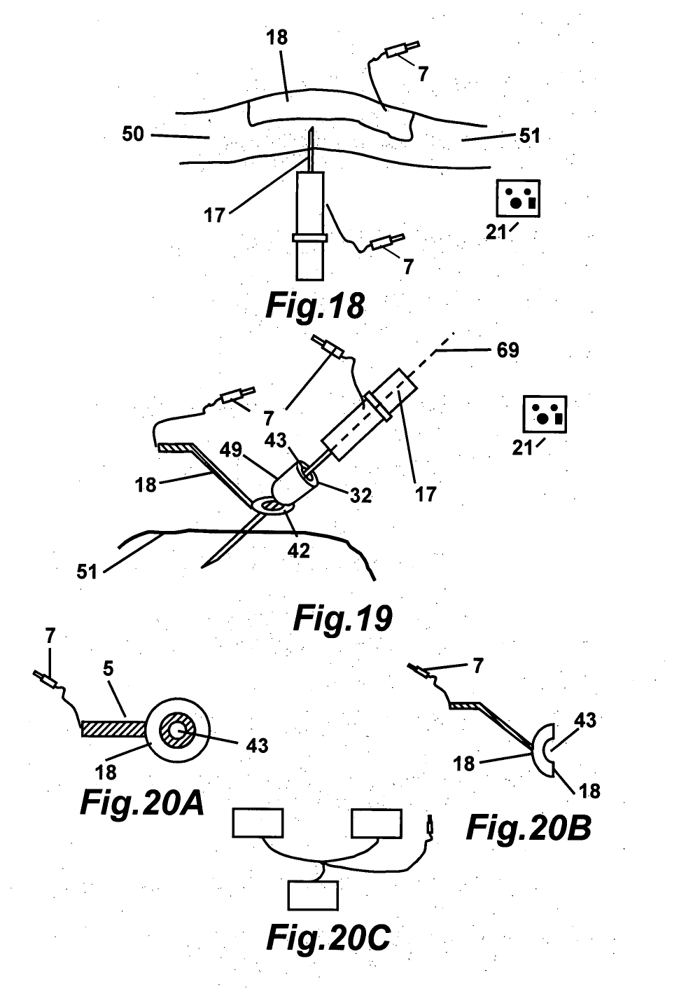

The invasive electrodes can also pass through the tissues 50 in order to reach the area containing the active agent as illustrated in FIG. 17 and FIG. 18. A guide 49 may be provided to make it possible to accurately position the place where the invasive electrode needs to penetrate the tissues and/or the angle of penetration of the axis 69 of the invasive electrode (exemplified in FIG. 19).

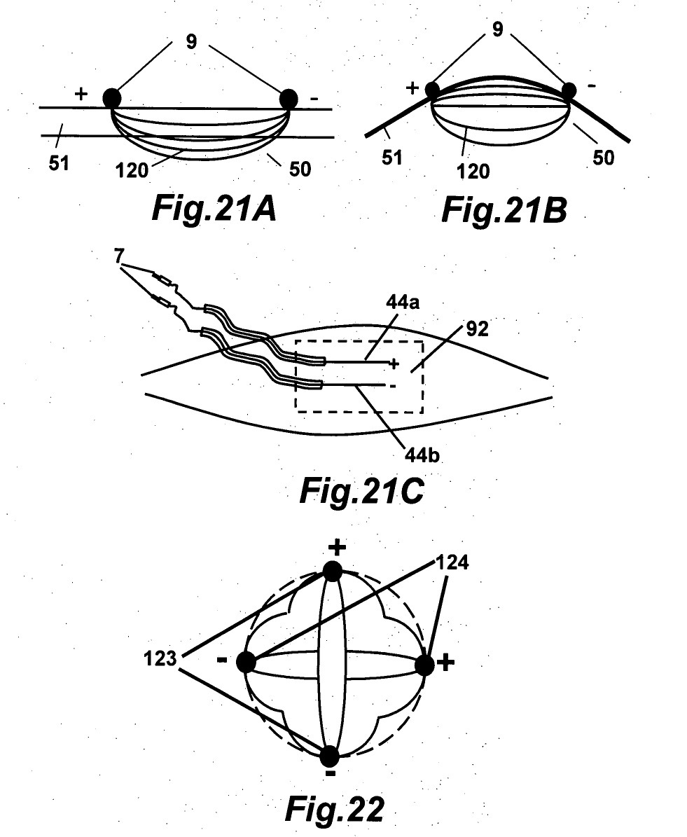

The two sets of electrodes can also be formed by non-invasive electrodes, joined together or maintained separately. The electrodes can face each other, or be applied to one and the same side of the tissues 51. The fields delivered 120 may be then propagated between the electrodes through a layer of intermediate tissues (skin, fat, etc) and passed through the tissues containing the active agent as exemplified in FIGS. 21.a and 21.b. FIG. 21.c shows an example of non-invasive wire electrodes.

The electrode device according to the invention may comprise several groups of at least two invasive electrodes located in the same area, the pulses being alternately delivered by the generator to each group. An example is illustrated by FIG. 22 for a device with two groups 123, 124, each consisting of a pair of two electrodes.

Emitting the pulses alternately to each group of electrodes may be advantageous. For example, this makes it possible to increase the overall pulse frequency throughout the tissue area (improving innocuousness) without increasing the frequency on each pair (possibly generating a drop in effectiveness).

Furthermore, if each group consists of only two electrodes, then the fields of each pulse emitted to each separate set of electrodes can be maintained if the latter are deformed, in particular because of the muscular contraction. They can be maintained at a maximum threshold and/or a minimum threshold, to a certain extent. The resistance between the electrodes is proportional to the average distance between the electrodes and the average field measured in volt/cm between the electrodes is inversely proportional to the average distance between the electrodes. According to the Ohm's law theorem U=RI, maintaining the current intensity emitted 134 while the electrodes are displaced should result in approximately maintaining the fields within the limit of the defined current intensity thresholds.

It is, however, an approximation, because if the electrodes are displaced, the nature (and therefore the conductivity) of the tissues passed through might vary. Furthermore, the passage of the current can slightly modify the conductive property of the tissues over time.

However, if a group contains more than two electrodes linked to one and the same power module 520 through the current intensity control module 550, then maintaining the current intensity on one pair of electrodes for which the distance between the electrodes varies will result in a significant change to the fields on the other pairs of electrodes.

The current intensity control module 550 may comprise a series resistance which then varies in order to maintain, automatically and in real time, the intensity below the maximum threshold and/or above the minimum threshold. This has the effect of proportionally varying the output voltage 130 once the current intensity thresholds are reached in order to keep the fields delivered approximately constant. In case of limiting to a lower threshold, the maximum voltage can preferably not exceed a certain voltage threshold for obvious tolerance reasons. Thus, if this voltage threshold is reached, the resistance should not vary any more in order to keep the voltage constant. An alternative could also be to stop the emissions of pulses by cutting off the direct current source 530 and signalling this situation.

The generator can make it possible to generate several successive series of pulses (with a predefined duration between two series) or simultaneous series.

A first set of electrodes 11 can be connected to a single electrode, called the central electrode, linked to a terminal of the generator linked to the earth, wherein the other electrodes and groups of electrodes 10 are linked to their respective terminals. Each terminal is linked to its power module 540 in order to emit its series of pulses. Thus, the devices described previously, in particular in FIGS. 5 to 6.c, 8.a to 10.2, 24.a and 24.b, can deliver simultaneous series of pulses, in which the central electrode 11 is linked to the common terminal 590a, and the external electrodes are linked individually or in groups to their respective power electrodes 590b, 590c, etc.

In practice, the number of series emitted simultaneously may be less than 16.

The programming of the pulses, i.e. the voltage 130, the number 133, the duration 132 and the interval 131, can take account of all or some of the following elements:

(i) the distance between the electrodes, in order to define the correct field value (V/cm),

(ii) the fact that the nature of the tissues and the required fields are different between muscle and tumour,

(iii) the geometry of the electrodes (invasive, non-invasive electrodes, form and number of the electrodes, etc),

(iv) the tolerance of the subject to electrotransfer; this is particularly valid for horses, as the induced reflex movements are able to cause sequelae if the fields delivered are too great,

(v) the tolerance of the region containing the tissues subject to the pulses, dependent in particular on the degrees of innervation of the tissues,

(vi) the potential toxicity of the treatment on the tissues treated, as the intensity emitted is able to destroy numerous cells, in particular by burning them or perforating them,

(vii) the effectiveness of the method, that is, in particular, the quantity of active products to be inserted into the tissues according to the quantity injected.

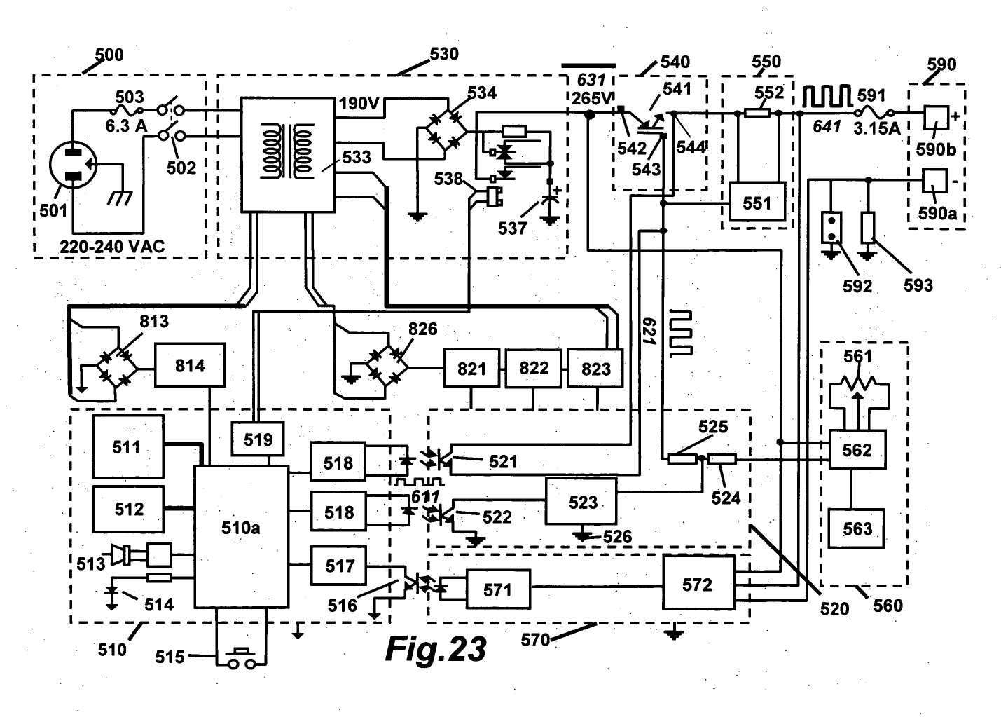

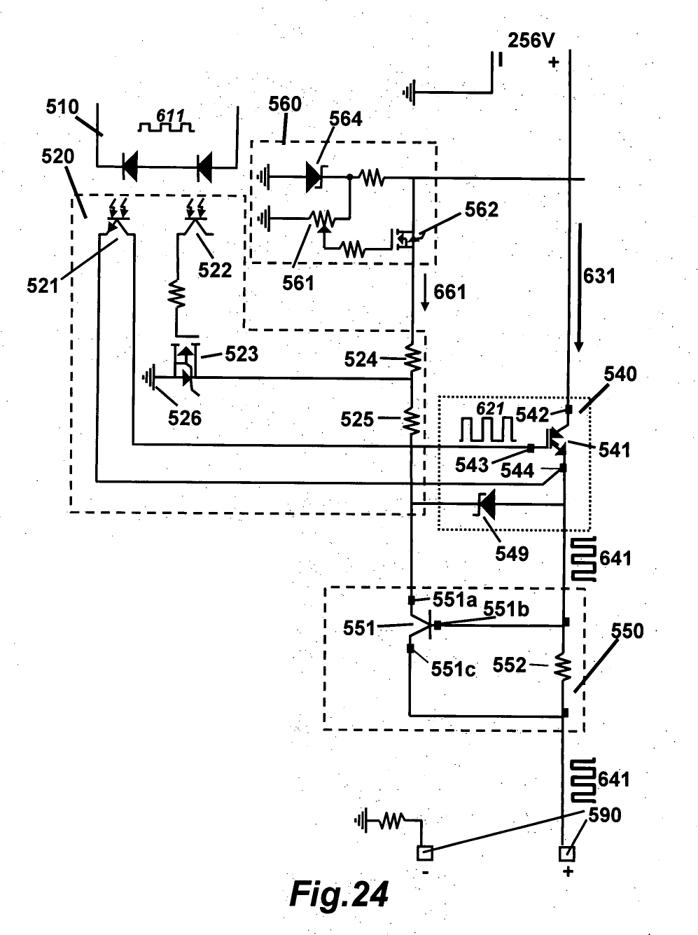

The generator may consist of a number of functional modules. It is exemplified in FIGS. 23 and 24.

It may comprise a signal source 510 which emits an electric signal 611 generated in PWM mode, consisting of a series of at least one TTL square pulse with a voltage, for example of 5 V. The electric signal 611 consists of a number of pulses 133, at least one pulse, and of a duration 132 of each pulse and a duration 131 between pulses. The signal may be generated by a microcontroller 510a which may comprise a RISC technology processor operating, for example, at 8 MHz. A user interface may comprise a keyboard 511, making it possible in particular to determine the characteristics of the signal, such as the number of pulses 133, the pulse duration 132 and the interval 131 between pulses. In addition, the interface may feature buttons, switches or any other user interface means, and can restore the information by means of one or more display device such as screens 512, indicator lamps 514 or sound indicators 513.

Further, programmed pulse sequences can be stored in a computer memory which can be incorporated in the microcontroller in order to be reused subsequently.

The generator can emit a beep while the pulses are being emitted in order to inform the operator.

Electric signal generation is triggered by pressing a button 515 linked to the microcontroller 510a, or by any other means (remote control, waves, computer, etc).

The electric signal 611 emitted by the microcontroller 510a can be transferred inverted to the required signal generator circuit 520 through a control circuit 518 comprising two opto-isolators 521 and 522. This circuit 520 may use a direct voltage generator circuit 560 to amplify the signal 611 to the voltage U130a taking into account this inversion. The voltage U130a is calculated according to the voltage difference U130b between the base 543 and emitter 544 of each power transistor 541 of the power module 540, so as to obtain the correct required voltage 130 (according to the rule U130a=U130b+130) at the emitter 544 of each power transistor 541.

The required voltage 130 can be specified by the operator, for example using a manual, motorized or programmable potentiometer 561. The voltage generator circuit 560 may comprise a series voltage stabilizer which consists of a zener diode 564, a potentiometer 561 and a transistor 562.

The output signal 621 obtained by the pulse amplifier circuit 520, 560 may be transmitted to the base 543 of each transistor 541 of the power module 540 and control the opening and closure of the power module 540 to divide up the current 631, in a manner described later in the present application.

The collector 542 of each transistor of the power module may be supplied by the constant voltage current 631 of the direct voltage source 530. This voltage can be generated from the mains via a power outlet 501. The power supply block 500 can include a fuse 503, for example a 6.3 A slow blow fuse, and a switch 502. The voltage may be first transformed to 190 V using a transformer 533, then rectified to 265 V using a rectifier 534, to finally be filtered using at least one capacitor 537.

The power module 540 may comprise at least two IGBT transistors 541 in parallel. In practice, two transistors might be needed in view of the high pulse parameters required. They can be used as a switch controlled by the amplified signal 621 output by the amplifier circuit 520, 560 to allow or stop the direct current 631, so that said direct current 631 is divided to take the exact form of the amplified signal 621. At the output of each transistor 541, the desired pulses 641 can be obtained, at the desired voltage 130, with amperage dependent on the resistance of the tissues between the electrodes linked to the output terminals 590.

In order to avoid the risks of a too large current intensity emitted by the electrodes, a fuse 591, for example 3.15 A, can be located at the output of the power module 540.

However, this protection might be insufficient and inoperative for numerous situations because it is too slow. Thus, the generator may have a real time current intensity control module 550 which may comprise a resistance 552 of low resistivity, for example around 20 ohms, and a transistor 551 having a collector 551a, a base 551b and an emitter 551c. This module 550 can be used to limit the current intensity to a predefined current intensity. It is necessary in cases of overload and excessively high voltage.

In another configuration, this module 550 could, instead of limiting the emitted current intensity, actuate a switch, in the form of a transistor, for example, and use a relay to cut off the current emitted 641 before it reaches the terminals 590, or cut off the current 631 at the direct voltage source 530, before it reaches the collector 542 of each power transistor 541.

FIG. 24 describes an operating agent of the intensity control module 550. It is based on the agent of a variable resistance, the value of which is zero as long the current intensity does not reach the predefined limit threshold. Once this threshold is reached, then the variable resistance increases as the current intensity from the power module 540 attempts to exceed this threshold, so as to fix the current intensity at this threshold. This resistance can in fact be formed by the power transistors 541 themselves.

Thus, when the current intensity of a pulse 641 reaches a predefined threshold, considered as the maximum allowed current intensity 135, then exceeds it very slightly (a difference of the order of a few thousandths of an amp), this is reflected in a low voltage increase between each end of the resistor 552, and therefore an increase in the voltage between the base 551b and the emitter 551c of the current intensity control transistor 551. If this voltage increase at the resistor 552 then exceeds a certain amplitude, such as around 0.5 V for certain transistors, this has the effect of opening the current intensity control transistor 551 and therefore allowing a current intensity to pass between its emitter 551c and its collector 551a. Consequently, the voltage between the base 543 and the emitter 544 of each power transistor 541 is reduced, which corresponds to an increase in the resistance of the transistor 541 between its collector 542 and its emitter 544. This causes a drop in current intensity 134, and therefore the desired result.

The resistivity of the resistor 552 can thus be calculated so that, at the moment when the current intensity 134 very slightly exceeds the threshold 135, the voltage difference at the terminals of the resistor corresponds to the opening threshold of the current intensity control transistor 551 (of the order of 0.5 V for example).

Conversely, at the moment when the drop in current intensity 134 (and therefore in the voltage at the resistor 552) obtained is sufficient, at the threshold 135, the current intensity control transistor 551 will be closed. This blocks the current between the emitter 551c and the collector 551a and cancels the resistance of the power transistors 541. The current emitted 134 can then increase again by a few thousandths of an ampere.

This succession of micro-interruptions makes it possible to limit the emitted current intensity.

Such an intensity control module permits a substantially instantaneous reactivity that is less than a microsecond.

In reality, the voltage emitted by the emitter of each power transistor 541, and therefore originally the voltage U130a, may take into account the slight loss of voltage due to the resistor 552 to obtain a voltage 130 at the terminals 590.

In addition, a measurement means, using a resistor 593 located just before the current output terminals 590, supplies the value of the emitted current intensity to a comparison means 570. This means can be used to compare in real time the information received with certain predefined values, and transmits information to the microcontroller if an anomaly is observed. Thus, it transmits, for example, the following events:

(i) zero current intensity,

(ii) current intensity reaching a high predefined value,

(iii) current intensity reaching a low predefined value,

(iv) operating anomaly on a power transistor 541 or another transistor or component.

The message can be transmitted using three optoisolators 516 through a control module 571 to an interface circuit 517 of the microcontroller.

The microcontroller, which can have a response time on the order of a tenth of an millisecond, will take the appropriate decisions for which it is programmed. For example, zero current intensity may display a warning message. Current intensity reaching a predefined value may stop generation of low signal 611 in order to stop emission of pulses or continue the series of pulses, depending on the choice of the operator. Furthermore, operating anomaly on the power transistor 541 may close, through the circuit 519, the relay 538 to cut off the current source 530, in particular if the transistor 541 blows.

These actions can be accompanied by a message on screen, a light and/or sound signal.

The manner in which the IGBT transistors generate the pulses is exemplified in FIG. 24. This method and this device can be used to obtain square pulses.

First of all, the device generates a direct current at the required voltage. To do so, a constant voltage current 631 of direct voltage source 530 at 265 V can be used, supporting current intensities up to 2.5 A and supplying the collector 542 of each transistor 541. This voltage can also used by the direct voltage generation circuit 560. This circuit may comprise a series voltage regulator consisting of a zener diode 564, a potentiometer 561, and a transistor 562, in particular MOSFET. This circuit delivers through the resistors 524 and 525 a voltage U130b (signal 661) between 9 and 259 V defined by the operator using the potentiometer 561. This voltage is then linked to the base 543 of each of the IGBT transistors 541.

In the exemplary embodiment, the voltage difference between the emitter 544 and the base 543 of each of the transistors 541 can be fixed at approximately 9 V, and depends on the characteristics of the power transistor 541. Here we have a second series voltage regulator, generating a voltage 130 produced in this case with the transistor 541.

The device also operates as a pulse generator, driven by the low signal 611 emitted by the microcontroller 510a, in order to divide up the emitted current 631 into required pulses. To do this, the following required signal generator circuit 520 has been produced.

The microcontroller generates a series of pulses 611 which is transmitted and inverted by the optoisolators 521 and 522.

When the zero signal, once transmitted and inverted, becomes high, the optoisolator 521 generates a short circuit between the base 543 of the power transistor 541 and its emitter 544, which has the effect of closing the transistor and blocking the current. The output voltage 130 is therefore almost zero, because a residual voltage remains. Simultaneously, the other optoisolators 522 open a transistor 523, preferably MOSFET, acting as a switch. The transistor then links the base 543 of the transistor 541 to the earth 526, which closes the transistor 541 and drains the residual voltage from the transistor 541 between two interruptions. This mechanism also prevents the risk of destruction of certain components at the time of the short circuit generated by the first optoisolator 521 (because the switch transistor 523 and the power transistors 541 can be damaged at high voltage).

Conversely, when the high signal, once transmitted and inverted, becomes virtually zero, the first optoisolator 522 closes the transistors 523 and isolates the base 543 of each power transistor 541 from the earth 526. The second optoisolator 521 cuts the link between the base and the emitter of the power transistor 541, and the voltage U130b is re-established.

At this moment, the voltage of the signal 631 is applied to the base of the power transistor 541, and therefore the pulse is generated at the required voltage 130.

In the duration 131 between two pulses, the switch transistor 523 is linked to the earth 526, and resistors may be implemented, because this is a short circuit situation that can damage the transistors 541 and 523 and the loads should be absorbed. Thus, a resistor 524 between the direct voltage generator 560 and the earth 526 and a resistor 525 between the base 542 of the power transistor 541 and the earth 526 can be provided.

The value of each of the resistors can be critical. Thus, it should not be too low, because it cannot then absorb the current effectively during the phases between two pulses 131, nor too high, which would reduce the effectiveness of each power transistor 541 during the pulse-generating phases 132. This value depends mainly on the characteristics of the transistors used, and can vary between 20 kohms and 560 kohms for the resistor 524 and 10 kohms and 470 kohms for the resistor 525.

The microcontroller 510a and the required signal generator circuit 520 are supplied by rectifiers 813, 826 and then by filters 814, 821, 822, 823.

The required voltage generator module 560 can be supplied from the direct voltage source 530.

A diode 549 can also be used to protect the transistors 541 of the power module.

Further, an output 592, which may be linked to representation and analysis appliances such as oscilloscope, computer or other, can be used to restore a signal indicating the current intensity and the voltage generated at the output terminals 590.

The generator delivers a series of pulses that are transmitted to the subject through electrodes of the electrode device, exemplified in a particular embodiment by FIGS. 12.a, 12.b and 12.c. It consists of a securing housing 6 and a set of three invasive electrodes assembled by a support also exemplified in FIG. 10.1.

The housing may consist of two half-cylinders 3, and the whole can be locked using a ring 22. The injection part 23 may comprise three electrodes that are aligned, parallel and of the same depth, the central electrode 11 being located equidistant between the two external electrodes 100, 101 and being used to inject the active agent. An orifice is provided to receive the syringe 1 which will contain the active agent which will be injected by the central electrode 11.

The needles can be assembled using one or two non conducting clamping disks 41. An electrically insulating film made of synthetic material 15 can also be applied to the upper part of the electrodes under the clamping disk 41.

The housing 6 may serve as a compartment for the injection part 23. It may also provide the electric connection with the electric terminals of the injection part 23 and the electric wires 7 linked to the generator 21. The two external electrodes 100, 101 of the injection part can be linked to the same terminal of the generator 590b, and the central electrode 11 can be linked to the other terminal 590a.

The housing 6 may comprise parts which, once assembled, make it possible to easily handle the electrode device 23. The contact can be made by metallic forms 38 pressed against the electrode by a spring or an elastic part, or even by flexible metallic blades. The housing 6 may also serve as a compartment for the syringe 1 containing the active agent 36 to be injected between the two external electrodes of the injection part 23. A stop system 20 makes it possible to drive in the needle electrodes to a predefined depth. FIG. 13 shows a cross section of the device with the injection part, consisting of the syringe and the assembled injection part, positioned in its compartment.

A program describing the (or each series of) pulses is defined, or a prerecorded program is selected, which defines in particular the number, from one to several, and the duration of each pulse, the interval between the pulses, the synchronization of the sequences, and the voltage to be applied between the electrodes.

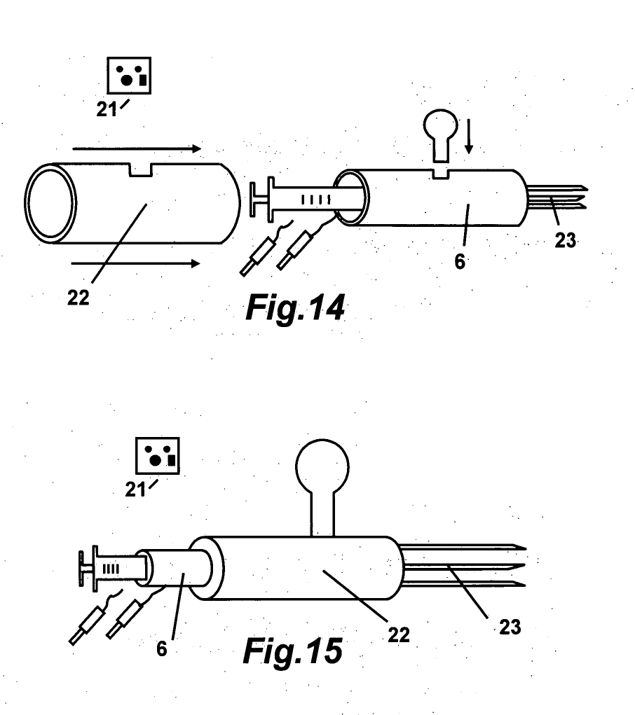

The syringe and its active product are assembled with the electrode part 23, and they are placed in the corresponding compartment of the housing. Then, the two half-cylinders are assembled, the housing 6 is locked by sliding on the locking cylinder 22, FIG. 14, and the stop 20 is inserted (FIG. 15). The electric terminals 7 are connected to the electric pulse generator 21, and the protective cap is removed from the needles 24. The device is ready (FIG. 15), and it can then be inserted into the tissues of the subject, according to the medical practices and movements normally practiced for inserting a needle provided with a syringe. The stop device blocks the device at a predefined intermediate depth. The active agent is injected, the stop is removed, and the housing is driven in as far as the guard.

It is now possible to trigger the (or each) preprogrammed series of pulses.

Then, the device can be removed from the subject, the housing can be unlocked and the disposable products (syringe 1, injection part 23) can be disposed of.

The pulses can also be emitted successively to each pair. Several means are proposed.

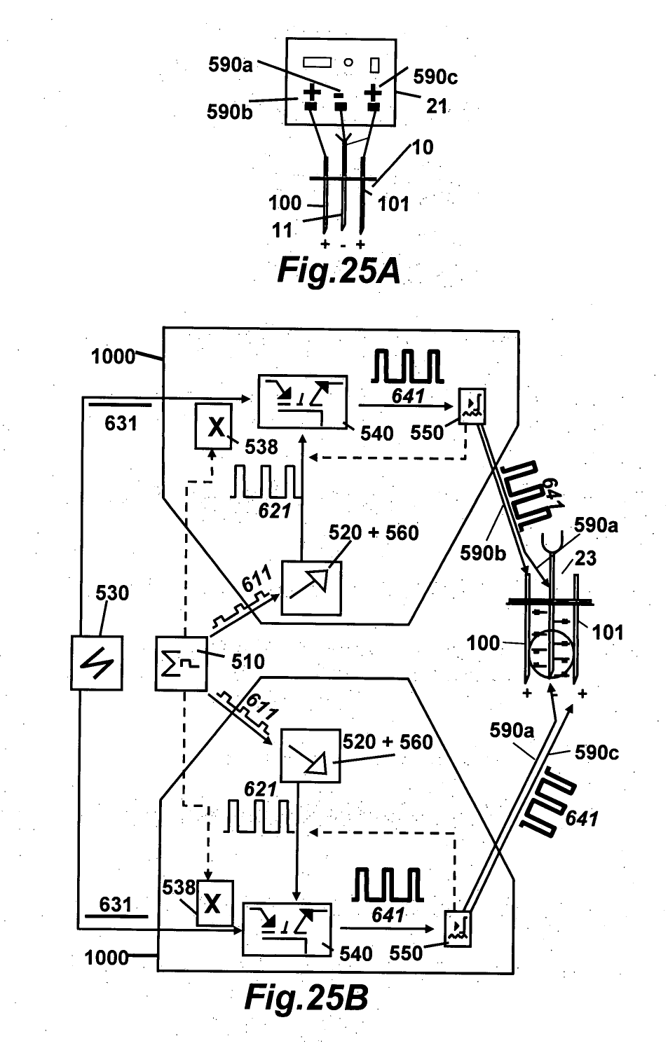

For example, it is possible to use an alternator module synchronized with the generator, by alternately placing in contact each external needle with the terminal 590b of the generator at the moment of the pulse emitted by the generator. In the embodiment illustrated in FIGS. 25.a and 25.b, the generator may deliver each pulse alternately to each pair of electrodes—pairs 101, 11 and 100, 11—wherein each pair is linked to its terminals. Thus electrode 100 is linked to the terminal 590b, electrode 101 is linked to the terminal 590c, and the electrode 11 is linked to the terminal 590a.

The terminal 590a, at zero voltage and linked to the earth, is common to the pairs of electrodes. Furthermore, in this example, the electrode device 23 consists of a central electrode 11 common to both pairs of electrodes. The generator has two pulse generation circuits 1000, each consisting of the circuits 520, 540, 550, 560. The direct voltage source 530 can be common. The low pulse generator means 510 can also be common, alternating the pulse to one or the other of the generator circuits 1000. The analysis circuit 570 can be common and/or be part of each circuit 1000. If the device comprises more than two external electrodes, then the number of circuits 1000 can be multiplied.

When a series of pulses at constant voltage is emitted between two invasive electrodes, and when the latter are moved, if the intensity reaches the predefined maximum threshold 135, the intensity control module 550 responds and reduces the voltage 130 in order to maintain the current intensity. This has the effect, with the resistance between the electrodes varying proportionally, of maintaining the fields V/cm between the two electrodes.

A device comprising a generator generating at least one unipolar electric square pulse of the preceding type can be implemented in a method adapted to improve in vivo penetration of active agent molecules into cells of tissues of a human or animal subject. Said method may comprise the following steps:

(1) placing at least one electrode electrically linked to the first terminal of the pulse generator 21 and at least one electrode electrically linked to the second terminal of the pulse generator 21 in contact with the tissues, and injection of the active agent 36 into the tissues,

(2) delivering square unipolar electric pulses by the generator 21, wherein the amplitude of said pulses is calculated according to the distance between the electrodes so as to create an electric field 12 between the electrodes; at least a part of the electric pulses are geometrically defined such that the voltage variations v1, v2 about the required voltage for each pulse are less than 5% of the required voltage, and duration t1 for the voltage to reach the required voltage from zero voltage (the ascendant phase of each pulse) and duration t2 for the voltage to reach zero voltage from the required voltage (the descendant phase of each pulse) are less than 5% of the duration of the pulse.

The pulses may be generated by hatching a current of a direct voltage source.

In the method, the pulses may be generated as follow:

(1) a direct voltage source 530 generates a current 631 at a constant voltage greater than the highest required voltage 130 for the pulses,

(2) a direct voltage generator 560 generates a voltage 661 at the amplitude U130a to the base 543 of each transistor 541 of the power module 540,

(3) a generator circuit for the required signal 520 divides up the voltage 661 according to the signal 611 consisting of the series of square pulses generated by the means 510, by means of the following components:

(i) an opto-isolator 521, which serves as a switch and, according to the pulses of the signal that consist of the series of square pulses 611, is used to short circuit the base 543 and the emitter 544 of each transistor 541 of the power module 540, thus rendering the current emitted 134 zero at the output terminals 590 of the generator during the period 131 between two pulses,
(ii) a transistor 523, which serves as a switch and, according to the pulses of signal that consist of the series of square pulses 611 inverted obtained through an opto-isolator 522, is used to link the voltage of the base 543 of each transistor 541 of the power module to earth 526,
(iii) a resistor 524 between 20 kohms and 560 kohms located between the direct voltage generator 560 and the switch transistor 523,
(iv) a resistor 525 between 10 kohms and 470 kohms located between the base 543 of each transistor 541 of the power module 540 and the switch transistor 523.

According to the method, in order to lower toxicity and pain caused by an intensity that is too large, the intensity can be limited in real time by maintaining the fields at a constant value since the electrodes get closer during electrotransfer. This can be made by an intensity control module 550. The control is performed by inducing a variable resistance which accordingly modifies the voltage delivered at the output terminals 590 of the pulse generator. The current intensity emitted is reduced by generating a current between the base 543 and the emitter 544 of each transistor 541 of the power module 540 as soon as the current intensity 134 very slightly exceeds a certain threshold 135. The voltage reduction between the base 543 and the emitter 544 of each transistor 541 of the power module 540 has the effect of inducing a resistance in each transistor 541 of the power module 540, and thus reduces the voltage 130 between the output terminals 590. Alternatively, the current intensity emitted is also reduced by no longer generating any current between the base 543 and the emitter 544 of each transistor 541 of the power module 540 once the current intensity 134 falls below the maximum current intensity threshold 135. The intensity control module reacting substantially instantaneously, in less than a microsecond.

In a particular embodiment, the intensity of the current can be interrupted in less than 200 microseconds.

The active agent can be administered with fields having a constant required voltage 130 less than 2000 V for each series of pulses, a duration 132 of each pulse between 1 and 1000 microseconds, and an interval 131 between two pulses between 1 and 1000 microseconds.

Further a device as described above makes it possible to implement a method to improve in vivo penetration of active agent molecules into the cells of the tissues of a human or animal subject, comprising the following steps:

(1) placing at least one group of electrodes in contact with the tissues to be treated, each electrode of the first set of electrodes 10 being electrically linked to a terminal 590b of a pulse generator 21 and each electrode of the second set of electrodes 11 being electrically linked to another terminal 590a of a pulse generator 21,

(2) injecting the active agent 36 into the area of tissues to be treated,

(3) setting the number of pulses 133, the duration of each pulse 132, and the duration between pulses 131 for each series of pulses to be delivered,

(4) setting the amplitude of the voltage of the electric signals to be delivered 130 for each series of pulses to be delivered,

(5) delivering square unipolar electric pulses, wherein the electric pulses are generated by the generator 21 in the following manner for each series of pulses:
(i) a signal 611 is generated, at a constant low voltage in PWM (mode, the signal corresponding to the form of the pulses required, i.e., interval 131, duration 132, number 133,
(ii) this signal 611 is used to divide the constant voltage current sent by a direct current source 530 in order to generate the required pulses in the correct form, interval 131, duration 132, number 133; the current generated is raised to the required voltage 130, and the pulses obtained then generate the electric field 120 required between the electrodes of each pair of electrodes, thus enabling penetration of the active agent into the cells of the tissues.

Further, for each series of pulses to be delivered, the amplitude of the voltage of the electric signals to be delivered 130 and the duration 132 and the interval 131 of the pulses can be set according to the distance between the electrodes and the geometry of the electrodes.

Those characteristics could also take into account the nature of the tissues, the tolerance of the subject to electrotransfer, the tolerance of the region containing the tissues subject to the pulses, and the potential toxicity of the treatment on the tissues being treated and the required effectiveness objectives.

In particular, the pulses 641 can be generated as follows:

(1) the signal 611 is generated using a computer method,

(2) said signal 611 is amplified to obtain a signal 621 at a voltage U130a greater than the required voltage 130 and with the required pulse shape, i.e., interval 131, duration 132, number 133,

(3) the power module 540 is used, comprising at least one transistor 541 to generate the required pulses, wherein the base 543 of each transistor 541 of the power module 540 is supplied with the amplified signal 621, and the collector 542 of each transistor 541 comprising a power module 540 is supplied with a direct voltage current 531,

The power module 540 then delivers a current 641 to the emitter 544 of each transistor, in which the form and the voltage correspond to the form and the voltage of the required pulses.

The pulses can be generated with the following method:

(1) a direct voltage 661 is generated at the amplitude U130a, in which the amplitude is equal to the required amplitude 130 plus the amplitude U130b between the base 543 and the emitter 544 of each transistor 541 of the power module 540; this direct voltage 661 is linked to the base 544 of each transistor of the power module 541,

(2) the voltage cited is divided according to the signal 611 emitted by the signal generator; to interrupt the current for the duration between two pulses 131, a short circuit is generated between the base 543 and the emitter 544 of each power transistor 541 in order to render the voltage U130b zero and also the output voltage at the terminals of the appliance 590, and simultaneously the base 543 of each power transistor 541 is linked to the earth, in order to drain the residual voltages; conversely, to allow the current to pass for the duration of each pulse 132, the short circuit between the base 543 and the emitter 544 of each power transistor 541 is eliminated, so restoring the voltage difference U13b, and the base 543 of each power transistor 541 is simultaneously insulated from the earth.

The generator can be set to automatically and immediately stop generating pulses if the current intensity sent 134 at the terminals 590 of this circuit exceeds a certain threshold 135.

The direct current source 530 may originate from a mains alternating energy power source 500 that has been transformed, then rectified, and finally filtered.

In the method, before delivering the fields, the following steps can be carried out:

(1) driving the device comprising at least two invasive electrodes 10, 11 successively into the tissues at intermediate depths, wherein each electrode is linked to a terminal of a pulse generator circuit 1000, and the device containing a means of injecting active agent, (2) injecting the active agent into the tissues at successive depths using the device, wherein the active agent is injected at the centre of the device,

(3) driving all of the invasive electrodes to a predefined final depth before triggering the delivery of the fields, wherein the invasive electrodes are introduced to the same depth into the tissues along the same axis.

The upper part of all invasive electrodes can be electrically insulated in order to avoid the passage of stray electric current 52 into the volume of tissue located between the electrodes and between the surface of the skin 51 and the tissue area containing the active agent 36.

In the method, the current intensity emitted 134 by each pulse can be limited to a predefined threshold 135 by proportionally and in real time reducing the voltage 130 of the pulses at the terminals 590 of the electrodes concerned.

In the method, the current intensity 134 can be regulated by inducing, in real time, a variable resistance at each transistor 541 of the power module 540. This resistance is generated by causing a voltage reduction between the base 543 and the emitter 544 of each power transistor 541 when the current intensity 134 exceeds a threshold 136 very slightly greater than the programmed current intensity threshold 135.

In the method, the voltage reduction between the base 543 and the emitter 544 of each transistor 541 is caused by means of a measurement resistor. The measurement resistor drives a transistor 551 used as a switch in the transmission of current between the base and the emitter of each transistor. Increasing the current intensity 134 above a certain threshold 135 leads to the opening of the transistor 551 and therefore current passing between the base 543 and the emitter 544 of each transistor 541. Conversely, lowering the intensity 134 below the threshold 135 leads to the closing of the transistor 551 and therefore stops the passage of current between the base 543 and the emitter 544 of each transistor 541.

For the implementation of the method, the various sets of electrodes 10, 11 linked to each circuit of the pulse generator 1000 can be applied roughly to the area of tissues containing the active agent. The generator 21 may be programmed to alternately emit electric pulses to each group of electrodes associated with one and the same circuit, in order to improve the innocuousness of the electric pulses by having a duration of the interval between two pulses over a group of electrodes greater than the duration of the interval between two pulses over the whole of the area receiving the electrodes.

In particular, each pulse generator circuit 1000 can be associated with a single pair of electrodes 10, 11 and the generator 21 can be programmed to alternately emit electric pulses from each pair of electrodes. This occurs in order to be able to independently limit the current intensity of each pulse on each pair of electrodes to a predetermined threshold 135 if the distance between the electrodes varies. This has the effect of keeping the fields V/cm delivered between the electrodes approximately constant once the predefined current intensity threshold is reached.

There are many industrial applications of the field-assisted administration of nucleotides. The device according to the invention is particularly intended for the administration of medicines, in particular DNA-based medicines, in human and veterinary medicine.

The therapeutic applications for humans and animals include, in particular, but obviously not exclusively, the treatment of tumours and the production of blood proteins.

The production of proteins in the blood concerns the treatment of haemophilia, growth problems, myopathies, lysosomal and metabolic illnesses in general, chronic renal inadequacy and beta-thalassemia by the endogenous production of erythropoietin. Other fields of application concern neoangiogenesis, atherosclerosis, using the protective effect of cytokines such as IL-10, vaccination, the use of antisense oligonucleotides, or even the prevention of peripheral neuropathy induced by cisplatin, by electrotransfer of a coding plasmid for a neurotrophin. Particular emphasis is currently placed on the use in articular rheumatoid polyarthritis or in inflammatory pathologies in general, using the protective effect of IL-10, anti-TNF or other cytokines. The use of growth factors is also rich in potential in neurodegenerative or articular degenerative (arthrosis) illnesses.

Furthermore, also concerned are all the pathologies that can benefit from the local expression of a secreted protein, such as an anti-inflammatory protein secreted in the joint for the treatment of arthritis, or an anti-angiogenic protein for the treatment of cancer. Similarly, the production in a joint of a growth factor can be considered for the treatment of arthrosis. The use of locally secreted angiogenic proteins for the treatment of peripheral arthritis can also be envisioned.

Also concerned are active and passive vaccination on human beings and animals, the production of vaccines and the production of antibodies, particularly in the field of bio-terrorism-linked pathologies. It is also important to mention the therapeutic applications for which the intracellular expression of a protein is necessary, such as numerous neuromuscular conditions (myopathy), tumours, etc.

The invention will now be further described by way of the following non-limiting examples which further illustrate the invention.

### EXAMPLES

### Example 1

### Prior State of the Art Methods

The generator of the present invention can emit a predefined number of pulses of each series having the following characteristics:

(i) the voltage of each pulse is identical,

(ii) the duration of each pulse is identical,

(iii) the interval between pulses is identical.

However, generally, these characteristics could be partly or totally removed.

A generator as described in the present application can offer results displaying an effectiveness of the active agent transfer in muscular cells that is twice those obtained by known generators or by application of pulses that are different from the square pulses of the above mentioned improved type.

Thus, the generator and square pulses of the above mentioned type may improve effectiveness of protein and plasmid, as well as any active agent as above defined, or any chemical molecule, in the tissues.

For example, an assay of plasmatic secreted alkaline phosphatase (SeAP) can be compared to an electrotransfer of a plasmid coding for this protein. For an injection of 800 μg of plasmid, the plasmatic concentrations of SeAP obtained compared to intramuscular electrotransfer are:

(1) 1800 ng/ml for SeAP (RIERA and al., 2004, The Journal of Gene Medecine, 6, 111-118),

(2) 2200 ng/ml for SeAP (BETTAN and al., 2000).

Furthermore, according to prior art, based on data obtained with other recombinant proteins expressed from electroporated plasmids, achievable plasmatic concentrations at peak should be in a range of 0.2 ng/ml to 1800 ng/ml. Furthermore, 10 ng/ml to 15 ng/ml at peak should appear to be a reasonable target for plasmatic concentration to be achieved by plasmid electrotransfer into a muscle.

Better results can be obtained by generators of the present application, that is by providing for fields or pulses of the above mentioned square type or by hatching a constant voltage current of a direct voltage source, which can be advantageously used to provide said square fields or pulses.

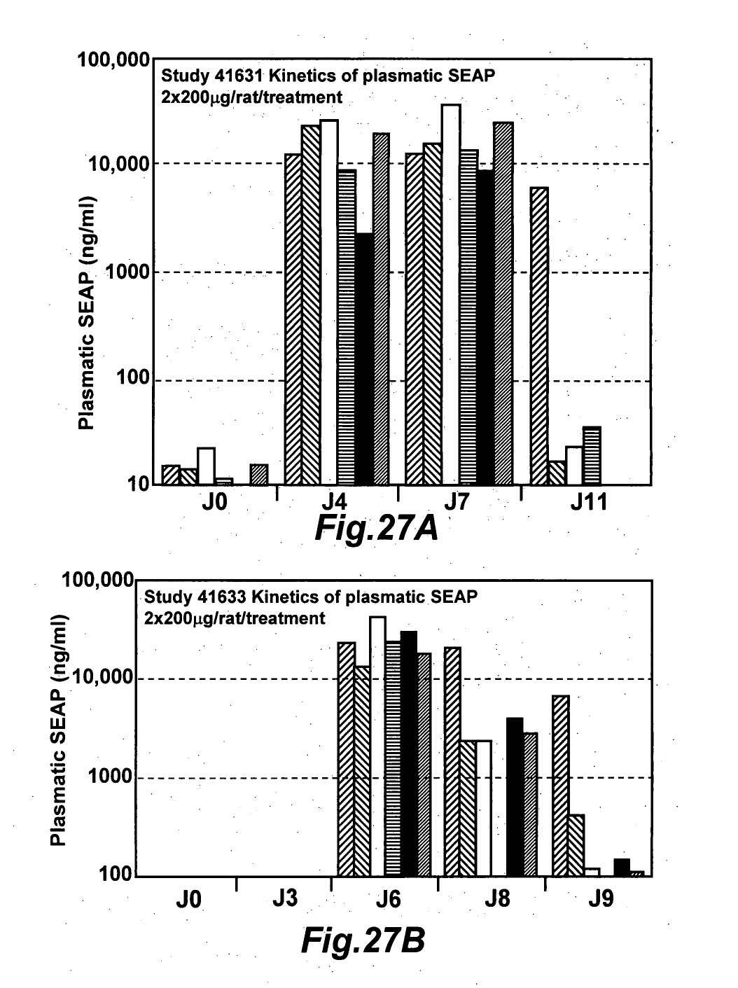

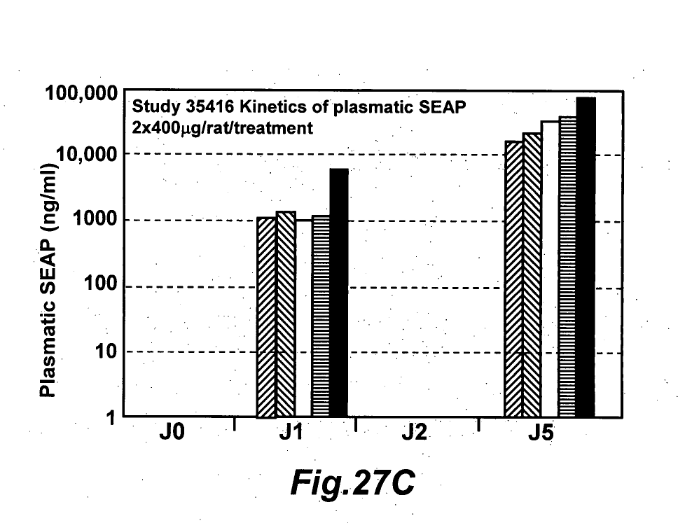

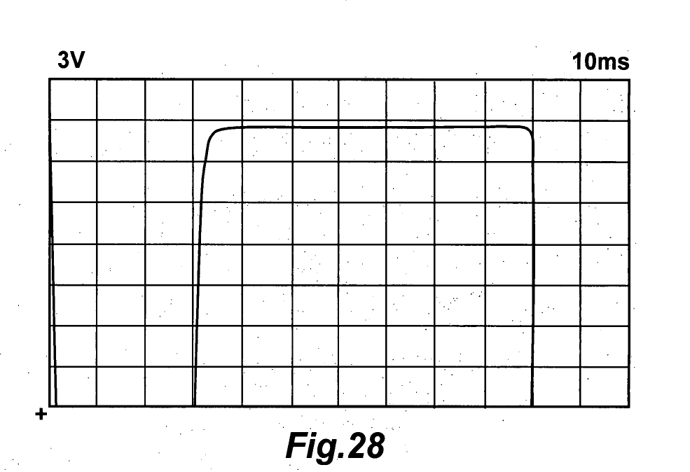

A series of three studies, referenced as study 41631 (FIG. 27.a), study 41633 (FIG. 27.b) and study 35416 (FIG. 27.c), has been performed the following way.

### Example 2

### Application of the Electrotransfer Technique Under Studies 41631, 41633, and 35416

The study 41631 was performed on six male Sprague-Dawley rats each weighting about 250 g.

On day J0, 400 μg of plasmid gWizSEAP (ALDEVERON) were administered to the six rats via intramuscular injection, i.e. 200 μg in 100 μl per leg, in the tibialis cranialis muscle. Electrotransfer was applied within 5 minutes after plasmid injection.

On day J4, 400 μg of plasmid gWizSEAP (ALDEVERON) were administered to the same six rats via intramuscular injection, i.e. 200 μg in 100 μl per leg, in the semi-membranosus muscle. Electrotransfer was applied within 5 minutes after plasmid injection.

Electrotransfer was applied under the following conditions:

(i) T1: 20 msec (duration of a pulse),

(ii) T2: 146 msec (interval between pulses),

(iii) frequency: 6 Hz,

(iv) number of pulses: 8,

(v) rectangular electrodes of about 0.8 cm², conductive gel (UP LIFT produced by Sant'ANGELICA) was placed between the shaved skin and the electrodes,

(vi) voltage of 140 V which corresponds to a field of 175 V/cm taking into account the distance between the electrodes, 0.8 cm.

Blood tests were performed on days J0, J4, J7 and J11 and a SeAP set of ROCHE APPLIED SCIENCES was used for the dosage of the SeAP.

The study 41633 was performed on six male Sprague-Dawley rats each weighting about 250 g.

On day J0, 400 μg of plasmid gWizSEAP (ALDEVERON) were administered to the six rats via intramuscular injection, i.e. 200 μg in 100 μl per leg, in the tibialis cranialis muscle. Electrotransfer was applied within 5 minutes after plasmid injection.

On day J3, 400 μg of plasmid gWizSEAP (ALDEVERON) were administered to the same six rats via intramuscular injection, i.e. 200 μg in 100 μl per leg, in the semi-membranosus muscle. Electrotransfer was applied within 5 minutes after plasmid injection.

Electrotransfer was applied under the following conditions:

(i) T1: 20 msec (duration of a pulse),

(ii) T2: 146 msec (interval between pulses),

(iii) frequency: 6 Hz,

(iv) number of pulses: 8,

(v) rectangular electrodes of about 0.8 cm², conductive gel (UP LIFT produced by Sant'ANGELICA) was placed between the shaved skin and the electrodes,

(vi) voltage of 140 V which corresponds to a field of 175 V/cm taking into account the distance between the electrodes, 0.8 cm.

Blood tests were performed on days J0, J3, J6, J8 and J9.

The study 35416 was performed on six male Sprague-Dawley rats each weighting about 250 g.

On day J0, 800 μg of plasmid gWizSEAP (ALDEVERON) were administered to the six rats via intramuscular injection, i.e. 400 μg in 100 μl per leg, in the tibialis cranialis muscle. Electrotransfer was applied within 5 minutes after plasmid injection.

Electrotransfer was applied under the following conditions:

(i) T1: 20 msec (duration of a pulse),

(ii) T2: 146 msec (interval between pulses),

(iii) frequency: 6 Hz,

(iv) number of pulses: 8,

(v) rectangular electrodes of about 0.8 cm², conductive gel (UP LIFT produced by Sant'ANGELICA) was placed between the shaved skin and the electrodes,

(vi) voltage of 140 V which corresponds to a field of 175 V/cm taking into account the distance between the electrodes, 0.8 cm.

Blood tests were performed on days J0, J1, and J5.

The results concerning group 3 and group 5 are represented respectively in FIG. 27.b and in FIG. 27.a.

Compared to intramuscular electrotransfer with a device of the present invention, injection of 400 μg of plasmid in a group of six rats gives a plasmatic concentration of SeAP between 10000 ng/ml and 40000 ng/ml, i.e. an increase of more than 500% compared to the results of the prior art where the pulses are not controlled, in contrast to those of the invention, and where the generator does not have the same structure as the present invention.

An example of square pulse generated in vivo by the device of the invention and applied to the tibialis cranilialis muscle of rat is represented on FIG. 28. In this example, the square pulse differs in a margin that is less than 1% from an exactly square pulse.

The invention is further described by the following numbered paragraphs:

1. A device for improving in vivo penetration of active agent molecules into cells of tissues of a human or animal subject, comprising:
(i) a generator of unipolar electric pulses adapted to generate at least one series of square unipolar electric pulses, wherein the generator comprises:
   (a) a means to enter a required voltage (130) for each series of pulses,
   (b) a means to enter a number (133) of pulses, a duration (132) of each pulse and an interval (131) between pulses for each series of pulses,
   (c) a means (510) to generate a signal consisting of a series of square pulses at a low and constant voltage (611) in PWM (Pulse Width Modulation) mode and that is in accordance to the form of the required pulses, i.e., having the required interval (131), duration (132), number (133),
   (d) a direct voltage source (530) generating a current (631) at a constant voltage greater than the highest required voltage (130) for the pulses,
   (e) at least one pulse generator circuit (1000), using said signal (611) to divide up the current (631) output by the direct voltage source (530) and generate at output terminals (590) a current (641) having the required voltage (130) and required pulse form, i.e., interval (131), duration (132), number (133),
(ii) at least one electrode device electrically linked to the at least one pulse generator circuit (1000) by output terminals (590), wherein each electrode device comprises:
   (a) a first set of electrodes comprising at least one electrode (10) electrically linked to a first terminal (590b) of the pulse generator circuit (1000),
   (b) a second set of electrodes comprising at least one electrode (11) electrically linked to a second terminal (590a) of the pulse generator circuit (1000),
(iii) a means (8) of injecting the active agent into the tissues.

2. Device according to Paragraph 1, wherein the means (510) adapted to generate the signal consisting of a series of square pulses (611) comprises a computer signal source (510a).

3. Device according to paragraphs 1 or 2, wherein each pulse generator circuit (1000) comprises:
(i) a power module (540) comprising at least one transistor (541) having a collector (542), a base (543) and an emitter (544),
(ii) a pulse amplifier circuit (520, 560) that comprises a means adapted to enter the required voltage (130) for the pulses, and generates, a signal (621) supplying the base (543) of each transistor (541) of the power module from the signal consisting of the series of square pulses (611), (540), the generated signal (621) having a voltage (U130a) equal to the required voltage (130) which is incremented by the voltage difference (U130b) between the base (543) and the emitter (544) of each transistor (541) of the power module (540), wherein the direct voltage source (530) is linked to the collector (542) of each transistor (541) of the power module (540),
   wherein the power module (540) consequently delivers, via the emitter (544) to the output terminals (590), a current (641) which is in the form corresponding to the series of pulses of the signal (611) and which has a voltage that corresponds to the required voltage (130) for the pulses.

4. Device according to paragraph 3, wherein each pulse generator circuit (1000) has a current intensity control module (550) adapted to limit, in real time to a predefined threshold (135), the current intensity of each pulse delivered at the output terminals (590) by inducing a variable resistance which accordingly modifies the voltage delivered at the output terminals (590).

5. Device according to paragraph 4, wherein the current intensity control module is adapted to cut off the current as the intensity between two electrodes reaches a predefined threshold.

6. Device according to Paragraph 4 or 5, wherein the current intensity control module (550) comprises a measurement resistor (552) and a control transistor (551) having a collector (551a), a base (551b) and an emitter (551c) controlled by the voltage difference on the measurement resistor (552), wherein the transistor is linked to one end of the measurement resistor (552) by the emitter (551c), to the base (543) of each transistor (541) of the power module (540) by the collector (551a), and to the emitter (544) of each transistor (541) of the power module (540) by the base (551b). which is also linked to the other end of the measurement resistor (552); and wherein the current intensity control module (550) can be used to reduce the current intensity emitted by

(i) generating a current between the base (543) and the emitter (544) of each transistor (541) of the power module (540) as soon as the current intensity (134) very slightly exceeds the threshold (135), the voltage reduction between the base (543) and the emitter (544) of each transistor (541) of the power module (540) having the effect of inducing a resistance in each transistor (541) of the power module (540), and thus reducing the voltage (130) between the output terminals (590),

(ii) no longer generating any current between the base (543) and the emitter (544) of each transistor (541) of the power module (540) once the current intensity (134) has fallen below the threshold (135).

7. Device according to any of paragraphs 3 to 6, wherein each power module (540) comprises at least one IGBT-type transistor (541).

8. Device according to any of paragraphs 3 to 6, wherein each power module (540) comprises at least one MOSFET-type transistor (541).

9. Device according to any of paragraphs 3 to 8, wherein each pulse amplifier circuit (520, 560) comprises a direct voltage generator (560) generating a voltage (661) at an amplitude (U130a) to the base (543) of each transistor (541) of the power module (540), and a generator circuit (520) for the required signal used to divide up the voltage (661) according to the signal consisting of the series of square pulses (611) generated by the means (510), wherein the generator circuit comprises the following components:
(i) an opto-isolator (521) which serves as a switch and, according to the pulses of the signal that consists of the series of square pulses (611), is used, to short circuit the base (543) and the emitter (544) of each transistor (541) of the power module (540) and thus render the emitted current (134) zero at the output terminals (590) of the generator during the period (131) between two pulses,
(ii) a transistor (523), which serves as a switch and, according to the pulses of signal that consists of the series of square pulses (611) inverted obtained through an opto-isolator (522), is used, to link the voltage of the base (543) of each transistor (541) of the power module to earth (526),
(iii) a resistor (524) between 20 kohms and 560 kohms located between the direct voltage generator (560) and the switch transistor (523),
(iv) a resistor (525) between 10 kohms and 470 kohms located between the base (543) of each transistor (541) of the power module (540) and the switch transistor (523).

10. Device according to any of paragraphs 3 to 9, wherein each pulse generator circuit (1000) has a control means (570) adapted to collect information on the emitted signals and currents and to transmit it to a computer means (510a) that can automatically, in the case of an anomaly or a maximum current intensity threshold overshoot, perform one of the following actions:
(i) stop the current before its arrival at the power module (540) using a circuit (538),
(ii) stop the generation of the signal (611),
(iii) signal the error situations to the operator,
(iv) take any preprogrammed logical action.

11. Device according to any of paragraphs 1 to 10, wherein the emitted pulses at the output terminals (590) of the generator are characterized in the following way:
(i) the voltage (130) of the emitted pulses is equal and constant for each pulse and is less than 500 V and
(ii) the duration of the interval (131) between the emitted pulses (131) is equal between each pulse and is between 1 and 150 ms and
(iii) the duration of the pulses (132) emitted is equal for each pulse and is between 1 and 100 ms and
(iv) the fields generated between each pair of electrodes (100, 101) are between 5 and 500 V/cm, and
(v) the current intensity (134) delivered at each instant while the fields are being delivered is less than 5 amps and
(vi) the total number of emitted pulses (132) for each series is less than 25,
(vii) the number of series emitted simultaneously is less than 16,
(viii) the total number of emitted series is less than 32.

12. Device according to any of paragraphs 1 to 11, wherein the electrode device (23) comprises:
(i) two invasive electrodes, each electrode being linked to an output terminal (590) of the generator and
(ii) a means of injecting the active agent consisting of an injection needle at intermediate depth and located at the centre of the two invasive electrodes wherein the electrodes and the injection needle are parallel, assembled, and joined together using a non-conducting support (41), and the electrodes are of the same depth.

13. Device according to any of paragraphs 1 to 11, wherein the electrode device (23) comprises:
(i) a first set of electrodes consisting of a central invasive electrode (11), and serving as a needle for injecting the active agent and linked to a zero terminal (590a) of the pulse generator circuit (1000),
(ii) a second set (10) consisting of external invasive electrodes located approximately on a circle of which the central electrode (11) is located at the centre, the external electrodes (10) being equidistant from each other, each external electrode (10) being linked to another terminal (590b) of the pulse generator circuit (1000),
   wherein, the electrodes of the two sets being parallel, of the same depth, assembled and joined together using a non-conductive support (41).

14. Device according to Paragraph 13, wherein the second set (10) of electrodes consists of four invasive electrodes.

15. Device according to Paragraph 13, wherein the second set (10) of electrodes consists of three invasive electrodes.

16. Device according to Paragraph 13, wherein the second set (10) of electrodes consists of two invasive electrodes, the three electrodes of the device being aligned.

17. Device according to any one of paragraphs 1 to 17, wherein the invasive electrodes of each electrode device (23) are joined together using a non-conductive support (41), and wherein each electrode device (23) also comprises a housing (6) having a compartment used to house the joined electrodes, the means of injecting the active agent, and a tank (1) containing the active agent, the housing allowing to correctly handle the electrodes and providing the electric link between each set of electrodes and its output terminal (590a, 590b).

18. Device according to Paragraph 17, wherein the housing (6) has a means for successively driving the invasive electrodes (10, 11) into the tissues to predefined intermediate depths, and has a means for injecting the active agent at stop position.

19. Device according to any one of the preceding paragraphs, wherein the upper part of the invasive electrodes of each electrode device (23), which penetrates into the tissues, is covered by an electric insulator (15).

20. Device according to any one of paragraphs 1 to 19, comprising only one pulse generator circuit (1000), simultaneously emitting a single series of pulses to two terminals (590) linked to a single electrode device (23).

21. A method using a device according to any of paragraphs 1 to 20 to improve in vivo penetration of active agent molecules into cells of tissues of a human or animal subject, the method comprising the following steps:
(1) placing at least one group of electrodes in contact with the tissues, each electrode of the first set of electrodes (10) being electrically linked to a terminal (590b) of a pulse generator (21) and each electrode of the second set of electrodes (11) being electrically linked to another terminal (590a) of a pulse generator (21),
(2) injecting the active agent (36) into the tissues,
(3) setting the number of pulses (133), the duration of each pulse (132) and the duration between pulses (131) for each series of pulses to be delivered,
(4) setting the required voltage for each series of pulses to be delivered, (130), and
(5) delivering square unipolar electric pulses, wherein the electric pulses generated by the generator (21) in the following manner for each series of pulses:
   (i) a signal (611) is generated, at a constant low voltage in PWM (Pulse Width Modulation) mode, the signal corresponding to the form of the pulses required, i.e., interval (131), duration (132), number (133),
   (ii) said signal (611) is used to divide the current output by a direct voltage source (530) and generate the required pulses in the correct form, interval (131), duration (132), number (133), the current generated being raised to the required voltage (130).

22. Method according to paragraph 21, further comprising a step wherein the required voltage (130) for each series of pulses to be delivered and the number (133), duration (132) and interval (131) of the pulses are set according to the distance between the electrodes and the geometry of the electrodes.

23. Method according to paragraphs 21 or 22, wherein the following steps are carried out before delivering the square unipolar electric pulses:
(1) driving successively into the tissues, at intermediate depths, the electrode device comprising at least two invasive electrodes (10μ, 11) each linked to a terminal of a pulse generator circuit (1000), the device containing a means of injecting active agent,
(2) injecting the active agent into the tissues at successive depths using the electrode device, the active agent being injected at the centre of the device, and
(3) driving to a predefined final depth all the invasive electrodes, the invasive electrodes being introduced to the same depth into the tissues, along the same axis.

24. A device for improving in vivo penetration of active agent molecules into cells of tissues of a human or animal subject, comprising:
(i) a generator of unipolar electric pulses adapted to generate at least one series of square unipolar electric pulses having the following features:
   (a) the pulses are geometrically defined such that the voltage variations (v1, v2) about a required voltage (V) for each pulse are less than 5% of the required voltage (V),
   (b) the pulses are geometrically defined such that the duration (t1) for the voltage to reach the required voltage from zero voltage (the ascendant phase of each pulse) and the duration (t2) for the voltage to reach zero voltage from the required voltage (the descendant phase of each pulse) are less than 5% of the duration of the pulse,
(ii) at least one electrode device electrically linked to output terminals (590) of the generator, each electrode device comprising:
   (a) a first set of electrodes comprising at least one electrode (10) electrically linked to a first terminal (590b) of the generator,
   (b) a second set of electrodes comprising at least one electrode (11) electrically linked to a second terminal (590a) of the generator,
(iii) a means (8) of injecting the active agent into the tissues.

25. Device according to paragraph 24, wherein the pulses are geometrically defined such that the voltage variations (v1, v2) about the required voltage for each pulse are less than 1% of the required voltage, and wherein the pulses are geometrically defined such that the duration (t1) of ascendant phase of each pulse and the duration (t2) of descendant phase of each pulse are less than 1% of the duration of the pulse.

26. Device according to paragraph 24 or 25, wherein the unipolar electric pulses generator comprises:
(i) a means to enter the required voltage (130) of the pulses for each series of pulses,
(ii) a means to enter a number (133) of pulses, a duration (132) of each pulse and an interval (131) between pulses for each series of pulses,
(iii) a means (510) to generate a signal that consists of a series of square pulses at a low and constant voltage (611) in PWM (Pulse Width Modulation) mode, and that is in accordance to the form of the required pulses, i.e., having the required interval (131), duration (132), number (133)
(iv) a direct voltage source (530) generating a current (631) at a constant voltage greater than the highest voltage required (130) for the pulses,
(vii) at least one pulse generator circuit (1000), using said signal (611) to divide up the current (631) output by the direct voltage source (530) and generate at the output terminals (590) a current (641) having the required voltage (130) and pulse form, i.e., interval (131), number (132), duration (133), for the series of pulses.

27. Device according to Paragraph 26, wherein the means (510) adapted to generate the signal consisting of a series of square pulses (611) comprises a computer signal source (510a).

28. Device according to paragraph 26 or 27, wherein: each pulse generator circuit (1000) comprises:
(i) a power module (540) comprising at least one transistor (541) having a collector (542), a base (543) and an emitter (544), and
(ii) a pulse amplifier circuit (520, 560) comprising a means adapted to enter the required voltage (130) for the pulses, and generating a signal (621) supplying the base (543) of each transistor (541) of the power module (540) from the signal consisting of the series of square pulses (611), the generated signal (621) having a voltage (U130a) equal to the required voltage (130) incremented by the voltage difference (U130b) between the base (543) and the emitter (544) of each transistor (541) of the power module (540),
   wherein the direct voltage source (530) is linked to the collector (542) of each transistor (541) of the power module (540),
   wherein the power module (540) consequently delivers, via the emitter (544) to the output terminals (590), a current in which the corresponds to the series of pulses of the signal (611) and in which the voltage corresponds to the required voltage (130) for the pulses.

29. Device according to paragraph 28, wherein each pulse generator circuit (1000) has a current intensity control module (550) adapted to limit, in real time to a predefined threshold (135), the current intensity of each pulse delivered at the output terminals (590) by inducing a variable resistance which accordingly modifies the voltage delivered at the output terminals (590).

30. Device according to paragraph 29, wherein the current intensity control module is adapted to cut off the current as the intensity between two electrodes reaches a predefined threshold.

31. Device according to Paragraph 29 or 30, wherein the current intensity control module (550) comprises a measurement resistor (552) and a control transistor (551) having a collector (551a), a base (551b) and an emitter (551c), controlled by the voltage difference across the measurement resistor (552), the transistor being linked to one end of the measurement resistor (552) by the emitter (551c), to the base (543) of each transistor (541) of the power module (540) by the collector (551a), and to the emitter (544) of each transistor (541) of the power module (540) by the base (551b) which is also linked to the other end of the measurement resistor (552), wherein the current intensity control module (550) can be used to reduce the current intensity emitted by:
(i) generating a current between the base (543) and the emitter (544) of each transistor (541) of the power module (540) as soon as the current intensity (134) very slightly exceeds the threshold (135), the voltage reduction between the base (543) and the emitter (544) of each transistor (541) of the power module (540) having the effect of inducing a resistance in each transistor (541) of the power module (540), and thus reducing the voltage (130) between the output terminals (590),
(ii) no longer generating any current between the base (543) and the emitter (544) of each transistor (541) of the power module (540) once the current intensity (134) has fallen below the threshold (135).

32. Device according to any of paragraphs 28 to 31, wherein each power module (540) comprises at least one IGBT-type transistor (541).

33. Device according to any of paragraphs 28 to 31, wherein each power module (540) comprises at least one MOSFET-type transistor (541).

34. Device according to any of paragraphs 28 to 33, wherein each pulse amplifier circuit (520, 560) comprises the following components:
(i) a direct voltage generator (560) generating a voltage (661) at an amplitude (U130a) to the base (543) of each transistor (541) of the power module (540),
(ii) a generator circuit (520) for the required signal used to divide up the voltage (661) according to the signal (611) consisting of the series of square pulses generated by the means (510), comprising the following components:
   (a) an opto-isolator (521) which serves as a switch and, according to the pulses of the signal that consists of the series of square pulses (611), is used to short circuit the base (543) and the emitter (544) of each transistor (541) of the power module (540) and thus render the emitted current (134) zero at the output terminals (590) of the generator during the period (131) between two pulses,
   (b) a transistor (523) which serves as a switch and, according to the pulses of signal that consists of the series of square pulses (611) inverted obtained through an opto-isolator (522), is used to link the voltage of the base (543) of each transistor (541) of the power module to earth (526),
   (c) a resistor (524) between 20 kohms and 560 kohms located between the direct voltage generator (560) and the switch transistor (523),
   (d) a resistor (525) between 10 kohms and 470 kohms located between the base (543) of each transistor (541) of the power module (540) and the switch transistor (523).

35. Device according to any of paragraphs 28 to 34, wherein each pulse generator circuit (1000) has a control means (570) adapted to collect information on the emitted signals and currents and to transmit it to a computer means (510a) that can automatically, in the case of an anomaly or a maximum current intensity threshold overshoot, perform one of the following actions:
(i) stop the current before its arrival at the power module (540) using a circuit (538),
(ii) stop the generation of the signals (611),
(iii) signal the error situations to the operator,
(iv) take any preprogrammed logical action.

36. Device according to any of paragraphs 26 to 35, wherein the emitted pulses at the output terminals (590) of the generator are characterized in the following way:
(i) the voltage (130) of the emitted pulses is equal and constant and is less than 500 V,
(ii) the duration of the interval (131) between the pulses (131) emitted is equal and between 1 and 150 ms and
(iii) the duration of the emitted pulses (132) is equal and between 1 and 100 ms,
(iv) the fields generated between each pair of electrodes (100, 101) are between 5 and 500 V/cm,
(v) the current intensity (134) delivered at each instant while the fields are being delivered is less than 5 amps and
(vi) the total number of emitted pulses (132) for each series is less than 25,
(vii) the number of series emitted simultaneously is less than 16, and
(viii) the total number of emitted series is less than 32.

37. Device according to any of paragraphs 26 to 36, wherein the electrode device (23) comprises two invasive electrodes, each electrode being linked to an output terminal (590) of the generator and a means of injecting the active agent consisting of an injection needle at intermediate depth located at the centre of the two invasive electrodes, wherein the electrodes and the injection needle are parallel, assembled, and joined together using a non-conducting support (41), and the electrodes are of the same depth.

38. Device according to any of paragraphs 26 to 36, wherein the electrode device (23) comprises:
(i) a first set of electrodes consisting of a central invasive electrode (11) and serving as a needle for injecting the active agent, wherein the electrode is linked to a zero terminal (590a) of the pulse generator circuit (1000), and
(ii) a second set (10) consisting of external invasive electrodes located approximately on a circle of which the central electrode (11) is located at the centre, the external electrodes (10) being equidistant from each other, each external electrode (10) being linked to another terminal (590b) of the pulse generator circuit (1000), wherein the electrodes of the two sets being parallel, of the same depth, assembled and joined together using a non-conductive support (41).

39. Device according to Paragraph 38, wherein the second set (10) of electrodes consists of four invasive electrodes.

40. Device according to Paragraph 38, wherein the second set (10) of electrodes consists of three invasive electrodes.

41. Device according to Paragraph 38, wherein the second set (10) of electrodes consists of two invasive electrodes, the three electrodes of the device being aligned.

42. Device according to any of paragraphs 26 to 41, wherein the invasive electrodes of each electrode device (23) are joined together using a non-conductive support (41) and wherein each electrode device (23) also comprises a housing (6) having a compartment used to house the joined electrodes and the means of injecting the active agent and a tank (1) containing the active agent, the housing allowing to correctly handle the electrodes and providing the electric link between each set of electrodes and its output terminal (590a, 590b).

43. Device according to Paragraph 42, wherein the housing (6) has a means for successively driving the invasive electrodes (10, 11) into the tissues to predefined intermediate depths, and has a means for injecting the active agent at stop position.

44. Device according to any of paragraphs 26 to 43, wherein the upper part of the invasive electrodes of each electrode device (23), which penetrates into the tissues, is covered by an electric insulator (15).

45. Device according to any of paragraphs 26 to 44, comprising only one pulse generator circuit (1000), simultaneously emitting a single series of pulses to two terminals (590) linked to a single electrode device (23).

46. Method implemented using a device according to any of paragraphs 24 to 45 to improve in vivo penetration of active agent molecules into cells of tissues of a human or animal subject, the method comprising the following steps:
(1) placing at least one electrode electrically linked to the first terminal of the pulse generator (21) and at least one electrode electrically linked to the second terminal of the pulse generator (21) in contact with the tissues, and injecting the active agent (36) into the tissues,
(2) delivering square unipolar electric pulses by the generator (21), wherein the amplitude of said pulses are calculated according to the distance between the electrodes to create an electric field (12) between the electrodes, at least a part of the electric pulses having the following features:
   (a) the pulses are geometrically defined such that the voltage variations (v1, v2) about the required voltage for each pulse are less than 5% of the required voltage,
   (b) the pulses are geometrically defined such that the duration (t1) of the ascendant phase of each pulse and the duration (t2) of descendant phase of each pulse are less than 5% of the duration of the pulse.

Having thus described in detail preferred embodiments of the present invention, it is to be understood that the invention defined by the above paragraphs is not to be limited to particular details set forth in the above description as many apparent variations thereof are possible without departing from the spirit or scope of the present invention.

1. A device for improving in vivo penetration of active agent molecules into cells of tissues of a human or animal subject, comprising:
(i) a generator of unipolar electric pulses adapted to generate at least one series of square unipolar electric pulses, wherein the generator comprises:
(a) a means to enter a required voltage (130) for each series of pulses,
(b) a means to enter a number (133) of pulses, a duration (132) of each pulse and an interval (131) between pulses for each series of pulses,
(c) a means (510) to generate a signal consisting of a series of square pulses at a low and constant voltage (611) in PWM (Pulse Width Modulation) mode and that is in accordance to the form of the required pulses, i.e., having the required interval (131), duration (132), number (133),
(d) a direct voltage source (530) generating a current (631) at a constant voltage greater than the highest required voltage (130) for the pulses,
(e) at least one pulse generator circuit (1000), using said signal (611) to divide up the current (631) output by the direct voltage source (530) and generate at output terminals (590) a current (641) having the required voltage (130) and required pulse form, i.e., interval (131), duration (132), number (133),
(ii) at least one electrode device electrically linked to the at least one pulse generator circuit (1000) by output terminals (590), wherein each electrode device comprises:
(a) a first set of electrodes comprising at least one electrode (10) electrically linked to a first terminal (590b) of the pulse generator circuit (1000),
(b) a second set of electrodes comprising at least one electrode (11) electrically linked to a second terminal (590a) of the pulse generator circuit (1000),
(iii) a means (8) of injecting the active agent into the tissues.

2. Device according to claim 1, wherein the means (510) adapted to generate the signal consisting of a series of square pulses (611) comprises a computer signal source (510a).

3. Device according to claim 1, wherein each pulse generator circuit (1000) comprises:
(i) a power module (540) comprising at least one transistor (541) having a collector (542), a base (543) and an emitter (544),
(ii) a pulse amplifier circuit (520, 560) that comprises a means adapted to enter the required voltage (130) for the pulses, and generates, a signal (621) supplying the base (543) of each transistor (541) of the power module from the signal consisting of the series of square pulses (611), (540), the generated signal (621) having a voltage (U130a) equal to the required voltage (130) which is incremented by the voltage difference (U130b) between the base (543) and the emitter (544) of each transistor (541) of the power module (540), wherein the direct voltage source (530) is linked to the collector (542) of each transistor (541) of the power module (540),
wherein the power module (540) consequently delivers, via the emitter (544) to the output terminals (590), a current (641) which is in the form corresponding to the series of pulses of the signal (611) and which has a voltage that corresponds to the required voltage (130) for the pulses.

4. Device according to claim 3, wherein each pulse generator circuit (1000) has a current intensity control module (550) adapted to limit, in real time to a predefined threshold (135), the current intensity of each pulse delivered at the output terminals (590) by inducing a variable resistance which accordingly modifies the voltage delivered at the output terminals (590).

5. Device according to claim 4, wherein the current intensity control module is adapted to cut off the current as the intensity between two electrodes reaches a predefined threshold.

6. Device according to claim 4, wherein the current intensity control module (550) comprises a measurement resistor (552) and a control transistor (551) having a collector (551a), a base (551b) and an emitter (551c) controlled by the voltage difference on the measurement resistor (552), wherein the transistor is linked to one end of the measurement resistor (552) by the emitter (551c), to the base (543) of each transistor (541) of the power module (540) by the collector (551a), and to the emitter (544) of each transistor (541) of the power module (540) by the base (551b). which is also linked to the other end of the measurement resistor (552); and wherein the current intensity control module (550) can be used to reduce the current intensity emitted by
(i) generating a current between the base (543) and the emitter (544) of each transistor (541) of the power module (540) as soon as the current intensity (134) very slightly exceeds the threshold (135), the voltage reduction between the base (543) and the emitter (544) of each transistor (541) of the power module (540) having the effect of inducing a resistance in each transistor (541) of the power module (540), and thus reducing the voltage (130) between the output terminals (590),
(ii) no longer generating any current between the base (543) and the emitter (544) of each transistor (541) of the power module (540) once the current intensity (134) has fallen below the threshold (135).

7. Device according to any of claim 3, wherein each power module (540) comprises at least one IGBT-type transistor (541).

8. Device according to any of claim 3, wherein each power module (540) comprises at least one MOSFET-type transistor (541).

9. Device according to claim 3, wherein each pulse amplifier circuit (520, 560) comprises a direct voltage generator (560) generating a voltage (661) at an amplitude (U130a) to the base (543) of each transistor (541) of the power module (540), and a generator circuit (520) for the required signal used to divide up the voltage (661) according to the signal consisting of the series of square pulses (611) generated by the means (510), wherein the generator circuit comprises the following components:
(i) an opto-isolator (521) which serves as a switch and, according to the pulses of the signal that consists of the series of square pulses (611), is used, to short circuit the base (543) and the emitter (544) of each transistor (541) of the power module (540) and thus render the emitted current (134) zero at the output terminals (590) of the generator during the period (131) between two pulses,
(ii) a transistor (523), which serves as a switch and, according to the pulses of signal that consists of the series of square pulses (611) inverted obtained through an opto-isolator (522), is used, to link the voltage of the base (543) of each transistor (541) of the power module to earth (526),
(iii) a resistor (524) between 20 kohms and 560 kohms located between the direct voltage generator (560) and the switch transistor (523),
(iv) a resistor (525) between 10 kohms and 470 kohms located between the base (543) of each transistor (541) of the power module (540) and the switch transistor (523).

10. Device according to claim 3, wherein each pulse generator circuit (1000) has a control means (570) adapted to collect information on the emitted signals and currents and to transmit it to a computer means (510a) that can automatically, in the case of an anomaly or a maximum current intensity threshold overshoot, perform one of the following actions:
(i) stop the current before its arrival at the power module (540) using a circuit (538),
(ii) stop the generation of the signal (611),
(iii) signal the error situations to the operator,
(iv) take any preprogrammed logical action.

11. Device according to claim 1, wherein the emitted pulses at the output terminals (590) of the generator are characterized in the following way:
(i) the voltage (130) of the emitted pulses is equal and constant for each pulse and is less than 500 V and (ii) the duration of the interval (131) between the emitted pulses (131) is equal between each pulse and is between 1 and 150 ms and
(iii) the duration of the pulses (132) emitted is equal for each pulse and is between 1 and 100 ms and
(iv) the fields generated between each pair of electrodes (100, 101) are between 5 and 500 V/cm, and
(v) the current intensity (134) delivered at each instant while the fields are being delivered is less than 5 amps and
(vi) the total number of emitted pulses (132) for each series is less than 25,
(vii) the number of series emitted simultaneously is less than 16,
(viii) the total number of emitted series is less than 32.

12. Device according to claim 1, wherein the electrode device (23) comprises:
(i) two invasive electrodes, each electrode being linked to an output terminal (590) of the generator and
(ii) a means of injecting the active agent consisting of an injection needle at intermediate depth and located at the centre of the two invasive electrodes wherein the electrodes and the injection needle are parallel, assembled, and joined together using a non-conducting support (41), and the electrodes are of the same depth.

13. Device according to claim 1, wherein the electrode device (23) comprises:
(i) a first set of electrodes consisting of a central invasive electrode (11), and serving as a needle for injecting the active agent and linked to a zero terminal (590a) of the pulse generator circuit (1000),
(ii) a second set (10) consisting of external invasive electrodes located approximately on a circle of which the central electrode (11) is located at the centre, the external electrodes (10) being equidistant from each other, each external electrode (10) being linked to another terminal (590b) of the pulse generator circuit (1000),
wherein, the electrodes of the two sets being parallel, of the same depth, assembled and joined together using a non-conductive support (41).

14. Device according to claim 13, wherein the second set (10) of electrodes consists of four invasive electrodes.

15. Device according to claim 13, wherein the second set (10) of electrodes consists of three invasive electrodes.

16. Device according to claim 13, wherein the second set (10) of electrodes consists of two invasive electrodes, the three electrodes of the device being aligned.

17. Device according to claims 1, wherein the invasive electrodes of each electrode device (23) are joined together using a non-conductive support (41), and wherein each electrode device (23) also comprises a housing (6) having a compartment used to house the joined electrodes, the means of injecting the active agent, and a tank (1) containing the active agent, the housing allowing to correctly handle the electrodes and providing the electric link between each set of electrodes and its output terminal (590a, 590b).

18. Device according to claim 17, wherein the housing (6) has a means for successively driving the invasive electrodes (10, 11) into the tissues to predefined intermediate depths, and has a means for injecting the active agent at stop position.

19. Device according to claim 1, wherein the upper part of the invasive electrodes of each electrode device (23), which penetrates into the tissues, is covered by an electric insulator (15).

20. Device according to claim 1, comprising only one pulse generator circuit (1000), simultaneously emitting a single series of pulses to two terminals (590) linked to a single electrode device (23).

21. A method using a device according to claim 1 to improve in vivo penetration of active agent molecules into cells of tissues of a human or animal subject, the method comprising the following steps:
(1) placing at least one group of electrodes in contact with the tissues, each electrode of the first set of electrodes (10) being electrically linked to a terminal (590b) of a pulse generator (21) and each electrode of the second set of electrodes (11) being electrically linked to another terminal (590a) of a pulse generator (21),
(2) injecting the active agent (36) into the tissues,
(3) setting the number of pulses (133), the duration of each pulse (132) and the duration between pulses (131) for each series of pulses to be delivered,
(4) setting the required voltage for each series of pulses to be delivered, (130), and
(5) delivering square unipolar electric pulses, wherein the electric pulses generated by the generator (21) in the following manner for each series of pulses:
(i) a signal (611) is generated, at a constant low voltage in PWM (Pulse Width Modulation) mode, the signal corresponding to the form of the pulses required, i.e., interval (131), duration (132), number (133),
(ii) said signal (611) is used to divide the current output by a direct voltage source (530) and generate the required pulses in the correct form, interval (131), duration (132), number (133), the current generated being raised to the required voltage (130).

22. Method according to claim 21, further comprising a step wherein the required voltage (130) for each series of pulses to be delivered and the number (133), duration (132) and interval (131) of the pulses are set according to the distance between the electrodes and the geometry of the electrodes.

23. Method according to claim 21, wherein the following steps are carried out before delivering the square unipolar electric pulses:
(1) driving successively into the tissues, at intermediate depths, the electrode device comprising at least two invasive electrodes (10, 11) each linked to a terminal of a pulse generator circuit (1000), the device containing a means of injecting active agent,
(2) injecting the active agent into the tissues at successive depths using the electrode device, the active agent being injected at the centre of the device, and
(3) driving to a predefined final depth all the invasive electrodes, the invasive electrodes being introduced to the same depth into the tissues, along the same axis.

24. A device for improving in vivo penetration of active agent molecules into cells of tissues of a human or animal subject, comprising:
(i) a generator of unipolar electric pulses adapted to generate at least one series of square unipolar electric pulses having the following features:
(a) the pulses are geometrically defined such that the voltage variations (v1, v2) about a required voltage (V) for each pulse are less than 5% of the required voltage (V),
(b) the pulses are geometrically defined such that the duration (t1) for the voltage to reach the required voltage from zero voltage (the ascendant phase of each pulse) and the duration (t2) for the voltage to reach zero voltage from the required voltage (the descendant phase of each pulse) are less than 5% of the duration of the pulse,
(ii) at least one electrode device electrically linked to output terminals (590) of the generator, each electrode device comprising:
(a) a first set of electrodes comprising at least one electrode (10) electrically linked to a first terminal (590b) of the generator,
(b) a second set of electrodes comprising at least one electrode (11) electrically linked to a second terminal (590a) of the generator,
(iii) a means (8) of injecting the active agent into the tissues.

25. Device according to claim 24, wherein the pulses are geometrically defined such that the voltage variations (v1, v2) about the required voltage for each pulse are less than 1% of the required voltage, and wherein the pulses are geometrically defined such that the duration (t1) of ascendant phase of each pulse and the duration (t2) of descendant phase of each pulse are less than 1% of the duration of the pulse.

26. Device according to claim 24, wherein the unipolar electric pulses generator comprises:
(i) a means to enter the required voltage (130) of the pulses for each series of pulses,
(ii) a means to enter a number (133) of pulses, a duration (132) of each pulse and an interval (131) between pulses for each series of pulses,
(iii) a means (510) to generate a signal that consists of a series of square pulses at a low and constant voltage (611) in PWM (Pulse Width Modulation) mode, and that is in accordance to the form of the required pulses, i.e., having the required interval (131), duration (132), number (133)
(iv) a direct voltage source (530) generating a current (631) at a constant voltage greater than the highest voltage required (130) for the pulses,
(vii) at least one pulse generator circuit (1000), using said signal (611) to divide up the current (631) output by the direct voltage source (530) and generate at the output terminals (590) a current (641) having the required voltage (130) and pulse form, i.e., interval (131), number (132), duration (133), for the series of pulses.

27. Device according to claim 26, wherein the means (510) adapted to generate the signal consisting of a series of square pulses (611) comprises a computer signal source (510a).

28. Device according to claim 26, wherein:
each pulse generator circuit (1000) comprises:
(i) a power module (540) comprising at least one transistor (541) having a collector (542), a base (543) and an emitter (544), and
(ii) a pulse amplifier circuit (520, 560) comprising a means adapted to enter the required voltage (130) for the pulses, and generating a signal (621) supplying the base (543) of each transistor (541) of the power module (540) from the signal consisting of the series of square pulses (611), the generated signal (621) having a voltage (U130a) equal to the required voltage (130) incremented by the voltage difference (U130b) between the base (543) and the emitter (544) of each transistor (541) of the power module (540),
wherein the direct voltage source (530) is linked to the collector (542) of each transistor (541) of the power module (540),
wherein the power module (540) consequently delivers, via the emitter (544) to the output terminals (590), a current in which the corresponds to the series of pulses of the signal (611) and in which the voltage corresponds to the required voltage (130) for the pulses.

29. Device according to claim 28, wherein each pulse generator circuit (1000) has a current intensity control module (550) adapted to limit, in real time to a predefined threshold (135), the current intensity of each pulse delivered at the output terminals (590) by inducing a variable resistance which accordingly modifies the voltage delivered at the output terminals (590).

30. Device according to claim 29, wherein the current intensity control module is adapted to cut off the current as the intensity between two electrodes reaches a predefined threshold.

31. Device according to claim 29, wherein the current intensity control module (550) comprises a measurement resistor (552) and a control transistor (551) having a collector (551a), a base (551b) and an emitter (551c), controlled by the voltage difference across the measurement resistor (552), the transistor being linked to one end of the measurement resistor (552) by the emitter (551c), to the base (543) of each transistor (541) of the power module (540) by the collector (551a), and to the emitter (544) of each transistor (541) of the power module (540) by the base (551b) which is also linked to the other end of the measurement resistor (552), wherein the current intensity control module (550) can be used to reduce the current intensity emitted by:
(i) generating a current between the base (543) and the emitter (544) of each transistor (541) of the power module (540) as soon as the current intensity (134) very slightly exceeds the threshold (135), the voltage reduction between the base (543) and the emitter (544) of each transistor (541) of the power module (540) having the effect of inducing a resistance in each transistor (541) of the power module (540), and thus reducing the voltage (130) between the output terminals (590),
(ii) no longer generating any current between the base (543) and the emitter (544) of each transistor (541) of the power module (540) once the current intensity (134) has fallen below the threshold (135).

32. Device according to claim 281, wherein each power module (540) comprises at least one IGBT-type transistor (541).

33. Device according to claim 28, wherein each power module (540) comprises at least one MOSFET-type transistor (541).

34. Device according to claim 28, wherein each pulse amplifier circuit (520, 560) comprises the following components:
(i) a direct voltage generator (560) generating a voltage (661) at an amplitude (U130a) to the base (543) of each transistor (541) of the power module (540),
(ii) a generator circuit (520) for the required signal used to divide up the voltage (661) according to the signal (611) consisting of the series of square pulses generated by the means (510), comprising the following components:
(a) an opto-isolator (521) which serves as a switch and, according to the pulses of the signal that consists of the series of square pulses (611), is used to short circuit the base (543) and the emitter (544) of each transistor (541) of the power module (540) and thus render the emitted current (134) zero at the output terminals (590) of the generator during the period (131) between two pulses,
(b) a transistor (523) which serves as a switch and, according to the pulses of signal that consists of the series of square pulses (611) inverted obtained through an opto-isolator (522), is used to link the voltage of the base (543) of each transistor (541) of the power module to earth (526),
(c) a resistor (524) between 20 kohms and 560 kohms located between the direct voltage generator (560) and the switch transistor (523),
(d) a resistor (525) between 10 kohms and 470 kohms located between the base (543) of each transistor (541) of the power module (540) and the switch transistor (523).

35. Device according to claim 28, wherein each pulse generator circuit (1000) has a control means (570) adapted to collect information on the emitted signals and currents and to transmit it to a computer means (510a) that can automatically, in the case of an anomaly or a maximum current intensity threshold overshoot, perform one of the following actions:
(i) stop the current before its arrival at the power module (540) using a circuit (538),
(ii) stop the generation of the signals (611),
(iii) signal the error situations to the operator,
(iv) take any preprogrammed logical action.

36. Device according to claim 26, wherein the emitted pulses at the output terminals (590) of the generator are characterized in the following way:
(i) the voltage (130) of the emitted pulses is equal and constant and is less than 500 V,
(ii) the duration of the interval (131) between the pulses (131) emitted is equal and between 1 and 150 ms and
(iii) the duration of the emitted pulses (132) is equal and between 1 and 100 ms,
(iv) the fields generated between each pair of electrodes (100, 101) are between 5 and 500 V/cm,
(v) the current intensity (134) delivered at each instant while the fields are being delivered is less than 5 amps and
(vi) the total number of emitted pulses (132) for each series is less than 25,
(vii) the number of series emitted simultaneously is less than 16, and
(viii) the total number of emitted series is less than 32.

37. Device according to claim 26, wherein the electrode device (23) comprises two invasive electrodes, each electrode being linked to an output terminal (590) of the generator and a means of injecting the active agent consisting of an injection needle at intermediate depth located at the centre of the two invasive electrodes, wherein, the electrodes and the injection needle are parallel, assembled, and joined together using a non-conducting support (41), and the electrodes are of the same depth.

38. Device according to claim 26, wherein the electrode device (23) comprises:
(i) a first set of electrodes consisting of a central invasive electrode (11) and serving as a needle for injecting the active agent, wherein the electrode is linked to a zero terminal (590a) of the pulse generator circuit (1000), and
(ii) a second set (10) consisting of external invasive electrodes located approximately on a circle of which the central electrode (11) is located at the centre, the external electrodes (10) being equidistant from each other, each external electrode (10) being linked to another terminal (590b) of the pulse generator circuit (1000),
wherein the electrodes of the two sets being parallel, of the same depth, assembled and joined together using a non-conductive support (41).

39. Device according to claim 38, wherein the second set (10) of electrodes consists of four invasive electrodes.

40. Device according to claim 38, wherein the second set (10) of electrodes consists of three invasive electrodes.

41. Device according to claim 38, wherein the second set (10) of electrodes consists of two invasive electrodes, the three electrodes of the device being aligned.

42. Device according to claim 26, wherein the invasive electrodes of each electrode device (23) are joined together using a non-conductive support (41) and wherein each electrode device (23) also comprises a housing (6) having a compartment used to house the joined electrodes and the means of injecting the active agent and a tank (1) containing the active agent, the housing allowing to correctly handle the electrodes and providing the electric link between each set of electrodes and its output terminal (590a, 590b).

43. Device according to claim 42, wherein the housing (6) has a means for successively driving the invasive electrodes (10, 11) into the tissues to predefined intermediate depths, and has a means for injecting the active agent at stop position.

44. Device according to claim 26, wherein the upper part of the invasive electrodes of each electrode device (23), which penetrates into the tissues, is covered by an electric insulator (15).

45. Device according to claim 26, comprising only one pulse generator circuit (1000), simultaneously emitting a single series of pulses to two terminals (590) linked to a single electrode device (23).

46. Method implemented using a device according to claim 24 to improve in vivo penetration of active agent molecules into cells of tissues of a human or animal subject, the method comprising the following steps:
(1) placing at least one electrode electrically linked to the first terminal of the pulse generator (21) and at least one electrode electrically linked to the second terminal of the pulse generator (21) in contact with the tissues, and injecting the active agent (36) into the tissues,
(2) delivering square unipolar electric pulses by the generator (21), wherein the amplitude of said pulses are calculated according to the distance between the electrodes to create an electric field (12) between the electrodes, at least a part of the electric pulses having the following features:
(a) the pulses are geometrically defined such that the voltage variations (v1, v2) about the required voltage for each pulse are less than 5% of the required voltage,
(b) the pulses are geometrically defined such that the duration (t1) of the ascendant phase of each pulse and the duration (t2) of descendant phase of each pulse are less than 5% of the duration of the pulse.
